(19) United States
(12) Patent Application Publication
(10) Pub. No.: US 2023/0116953 A1
(43) Pub. Date: Apr. 20, 2023

(54) SUBSTRATE RETAINER, SUBSTRATE PROCESSING APPARATUS AND METHOD OF MANUFACTURING SEMICONDUCTOR DEVICE

(71) Applicant: Kokusai Electric Corporation, Tokyo (JP)

(72) Inventors: Atsushi HIRANO, Toyama-shi (JP); Hironori Shimada, Toyama-shi (JP)

(73) Assignee: Kokusai Electric Corporation, Tokyo (JP)

(21) Appl. No.: 18/068,692

(22) Filed: Dec. 20, 2022

Related U.S. Application Data
(63) Continuation of application No. PCT/JP2020/033297, filed on Sep. 2, 2020.

(51) Int. Cl. H01L 21/673; H01L 21/677; C23C 16/458; C23C 16/46

(52) U.S. Cl. CPC H01L 21/67309; H01L 21/67757; C23C 16/4584; C23C 16/46

(57) ABSTRACT

According to the present disclosure, there is provided a technique capable of improving a strength of a substrate retainer. According to one aspect of the technique of the present disclosure, there is provided a substrate retainer including: annular structures arranged at predetermined intervals; support columns configured to support the annular structures and provided along outer edges of the plurality of annular structures, wherein a width of each of the support columns is smaller than a width of each of the annular structures; support structures extending from the support columns toward a radially inward direction and configured to support a substrate between two adjacent annular structures; and connecting structures welded to at least one of the support columns and to the annular structures so as to connect the at least one of the support columns with the annular structures.

### CROSS-REFERENCE TO RELATED PATENT APPLICATIONS

This application is a bypass continuation application of PCT International Application No. PCT/JP2020/033297, filed on Sep. 2, 2020, in the WIPO, the entire contents of which are hereby incorporated by reference.

### BACKGROUND OF THE INVENTION

### 1. Field

The present disclosure relates to a substrate retainer, a substrate processing apparatus and a method of manufacturing a semiconductor device.

### 2. Related Art

In a substrate processing apparatus according to some related arts, a film is formed on a surface of a substrate while a plurality of substrates including the substrate are being held (or supported) by a substrate retainer in a process furnace in a multistage manner.

The substrate retainer used in the substrate processing apparatus described above may include: a plurality of support columns; a plurality of substrate supporting structures provided in a longitudinal direction of the plurality of support columns; and a plurality of ring-shaped plates arranged alternately with the plurality of substrate supporting structures in the longitudinal direction of the plurality of support columns. By engaging the plurality of support columns with a plurality of notches provided in the plurality of ring-shaped plates and directly welding the plurality of ring-shaped plates and the plurality of support columns, the plurality of ring-shaped plates are fixed to the plurality of support columns.

However, in the substrate retainer described above, in order to secure a substrate transfer region through which the plurality of substrates are transferred to the plurality of substrate supporting structures, respectively, the plurality of support columns are concentrated within a semicircular portion of the plurality of ring-shaped plates. In such a state, the plurality of ring-shaped plates and the plurality of support columns are directly welded and fixed as described above. Thus, when the plurality of ring-shaped plates are bent downward (droop or sag) at a portion where the plurality of support columns are not provided, a stress is concentrated at fixing portions between the plurality of ring-shaped plates and the plurality of support columns. As a result, the substrate retainer may be easily damaged.

### SUMMARY OF THE INVENTION

According to the present disclosure, there is provided a technique capable of improving a strength of a substrate retainer.

According to one aspect of the technique of the present disclosure, there is provided a substrate retainer including: a plurality of annular structures arranged at predetermined intervals; a plurality of support columns configured to support the plurality of annular structures and provided along outer edges of the plurality of annular structures, wherein a width of each of the plurality of support columns is smaller than a width of each of the plurality of annular structures; a plurality of support structures extending from the plurality of support columns toward a radially inward direction and configured to support a substrate between two adjacent annular structures among the plurality of annular structures; and a plurality of connecting structures welded to at least one of the plurality of support columns and to the plurality of annular structures so as to connect the at least one of the plurality of support columns with the plurality of annular structures.

### BRIEF DESCRIPTION OF THE DRAWINGS

FIG. 1 is a diagram schematically illustrating a substrate processing apparatus according to one or more embodiments of the present disclosure.

FIG. 2 is a diagram schematically illustrating a horizontal cross-section of the substrate processing apparatus according to the embodiments of the present disclosure.

FIG. 3 is a diagram schematically illustrating a vertical cross-section of the substrate processing apparatus according to the embodiments of the present disclosure.

FIG. 4A is a diagram schematically illustrating a positional relationship among a substrate supported by a substrate retainer according to the embodiments of the present disclosure, an annular structure and a supply slit.

FIG. 4B is a diagram schematically illustrating an enlarged view of a part of FIG. 4A.

FIGS. 5A through 5D are diagrams schematically illustrating a perspective view, a side view, a top view and a bottom view, respectively, of the substrate retainer according to the embodiments of the present disclosure.

FIG. 6 is a diagram schematically illustrating a perspective view of the annular structure according to the embodiments of the present disclosure.

FIG. 7 is a diagram schematically illustrating a horizontal cross-section of the substrate retainer according to the embodiments of the present disclosure.

FIG. 8A is a diagram schematically illustrating a periphery of a fixing portion between the annular structure and a support column when viewed from above, FIG. 8B is a diagram schematically illustrating the periphery of the fixing portion between the annular structure and the support column when viewed from an outer circumference of the support column, and FIG. 8C is a diagram schematically illustrating a perspective view of the periphery of the fixing portion between the annular structure and the support column.

FIG. 9A is a diagram schematically illustrating a perspective view of the substrate retainer according to the embodiments of the present disclosure in a state where a plurality of substrates are supported by the substrate retainer, FIG. 9B is a diagram schematically illustrating a perspective view of an enlarged vertical cross-section of a part of FIG. 9A, and FIG. 9C is a diagram schematically illustrating the enlarged vertical cross-section of the part of FIG. 9A.

FIG. 10 is a block diagram schematically illustrating a configuration of a controller and related components of the substrate processing apparatus according to the embodiments of the present disclosure.

FIG. 11 is a diagram schematically illustrating an exemplary film-forming sequence of the substrate processing apparatus according to the embodiments of the present disclosure.

FIG. 12A is a diagram schematically illustrating a horizontal cross-section of the substrate retainer according to a comparative example, and FIG. 12B is a diagram schematically illustrating an enlarged view of a periphery of a fixing portion between an annular structure and a support column in a region “A” of FIG. 12A.

FIG. 13A is a diagram schematically illustrating a relationship among a thickness of the annular structure, a stress applied to the fixing portion between the annular structure and the support column and a bending amount of the annular structure, FIG. 13B is a diagram schematically illustrating a relationship between the thickness of the annular structure and a gas inflow rate to the substrate, and FIG. 13C is a diagram schematically illustrating a relationship between an inner diameter of the annular structure and the gas inflow rate to the substrate.

FIG. 14A is a diagram schematically illustrating a relationship between a position of the support column from a central axis of the substrate retainer and the bending amount of the annular structure, and FIG. 14B is a diagram schematically illustrating a relationship between the position of the support column from the central axis of the substrate retainer and the stress applied to the fixing portion between the annular structure and the support column.

FIG. 15A is a diagram schematically illustrating a modified example of the substrate retainer according to the embodiments of the present disclosure, more specifically, illustrating a perspective view of the periphery of the fixing portion between the annular structure and the support column according to the modified example, FIG. 15B is a diagram schematically illustrating another modified example of the substrate retainer according to the embodiments of the present disclosure, and FIG. 15C is a diagram schematically illustrating the periphery of the fixing portion between the annular structure and the support column according to the another modified example shown in FIG. 15B when viewed from the outer circumference of the support column.

### DETAILED DESCRIPTION

### Embodiments

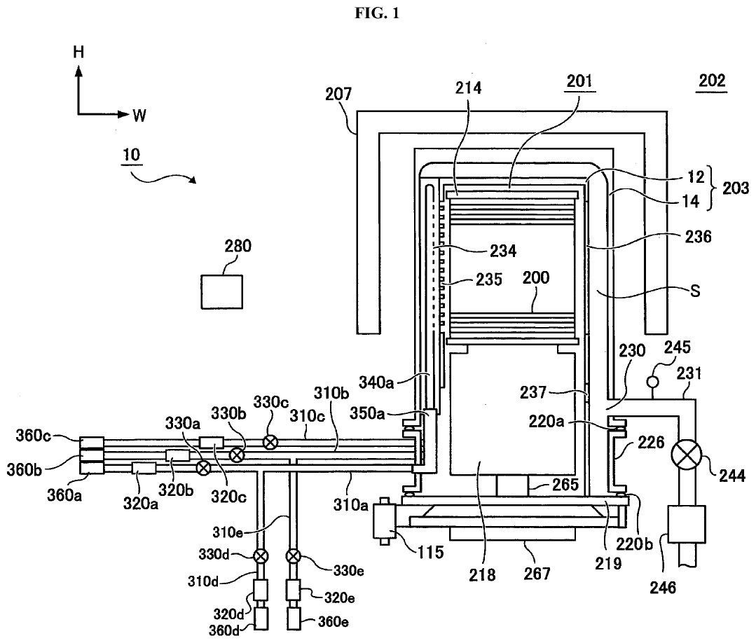

Hereinafter, an example of a substrate processing apparatus 10 according to one or more embodiments (also simply referred to as “embodiments”) of the technique of the present disclosure will be described with reference to FIGS. 1 through 11. In the figures, a direction indicated by an arrow H represents a up-and-down direction (that is, a vertical direction) of the substrate processing apparatus 10, a direction indicated by an arrow W represents a width direction (that is, a horizontal direction) of the substrate processing apparatus 10, and a direction indicated by an arrow D represents a depth direction (that is, another horizontal direction) of the substrate processing apparatus 10.

<Overall Configuration of Substrate Processing Apparatus 10>

As shown in FIG. 1, the substrate processing apparatus 10 includes a process furnace 202 and a controller 280 configured to be capable of controlling components constituting the substrate processing apparatus 10, and the process furnace 202 includes a heater 207 configured to heat a plurality of wafers including a wafer 200. Hereinafter, the plurality of wafers including the wafer 200 may also be simply referred to as “wafers 200”. The heater 207 is of a cylindrical shape, and is configured to surround a reaction tube 203. The heater 207 is installed in the up-and-down direction (that is, the vertical direction) of the apparatus (that is, the substrate processing apparatus 10) by being supported by a heater base (not shown). The heater 207 also functions as an activator (which is an activating structure) capable of activating a gas such as process gases by a heat. The controller 280 will be described later in detail.

The reaction tube 203 is disposed vertically inside the heater 207. A reaction vessel is constituted by the reaction tube 203 which is aligned in a manner concentric with the heater 207. For example, the reaction tube 203 is made of a heat resistant material such as a high-purity fused quartz (SiO₂) and silicon carbide (SiC). For example, the substrate processing apparatus 10 is a so-called hot wall type apparatus.

The reaction tube 203 is constituted by an inner tube 12 that directly faces the wafers 200 and an outer tube 14 of a cylindrical shape that surrounds the inner tube 12 with a wide gap (that is, a gap S) outside of the inner tube 12. The reaction tube 203 includes a side surface and a ceiling, and the side surface of the reaction tube 203 is configured as a cylindrical surface whose axis is coaxial with a rotating shaft 265 described later. The inner tube 12 is arranged in a manner concentric with the outer tube 14. The inner tube 12 serves as an example of a tube structure. The outer tube 14 is pressure-resistant.

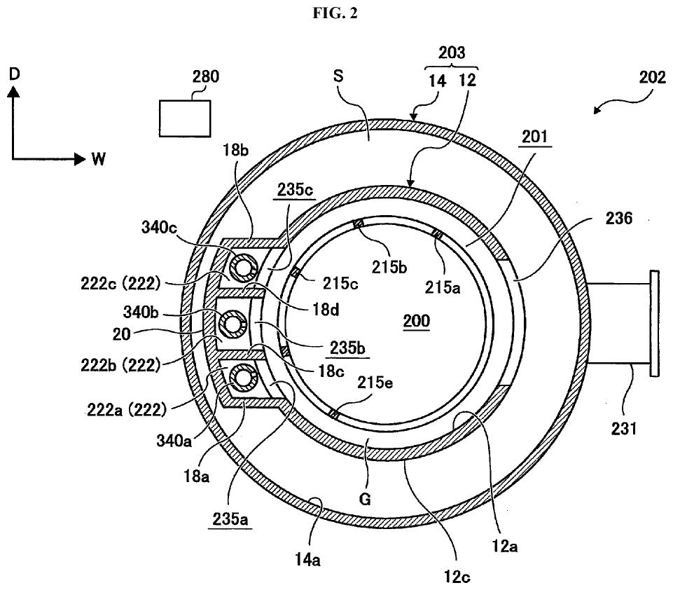

A lower end of the inner tube 12 is open and an upper end of the inner tube 12 is closed by a flat ceiling. Further, similar to the inner tube 12, a lower end of the outer tube 14 is open and an upper end of the outer tube 14 is completely closed by a flat ceiling. In addition, in the gap S provided between the inner tube 12 and the outer tube 14, as shown in FIG. 2, a plurality of nozzle chambers (for example, three nozzle chambers according to the present embodiments) 222 are provided. The nozzle chambers 222 will be described later in detail.

As shown in FIGS. 1 and 2, a process chamber 201 in which the wafer 200 serving as a substrate is processed is provided in a space surrounded by a side surface of the inner tube 12 and the ceiling of the inner tube 12. Further, the process chamber 201 is configured such that a boat 214 serving as an example of a substrate retainer is capable of being accommodated in the process chamber 201. The boat 214 is configured such that the wafers 200 are capable of being accommodated in a horizontal orientation in a multistage manner in the boat 214 to be arranged along the vertical direction. When the boat 214 is accommodated in the process chamber 201, the inner tube 12 surrounds the wafers 200 accommodated in the boat 214. The inner tube 12 will be described later in detail.

A lower end of the reaction tube 203 is supported by a manifold 226 of a cylindrical shape. For example, the manifold 226 is made of a metal such as nickel alloy and stainless steel, or is made of a heat and corrosion resistant material such as quartz and SiC. A flange (not shown) is provided at an upper end of the manifold 226, and a lower end of the outer tube 14 is provided on the flange and supported by the flange. A seal 220a such as an O-ring is provided between the flange and the lower end of the outer tube 14 to airtightly seal an inside of the reaction tube 203.

A lid (seal cap) 219 is airtightly attached to a lower end opening of the manifold 226 via a seal 220b such as an O-ring. The lid 219 is configured to airtightly seal a lower end opening of the reaction tube 203, that is, the lower end opening of the manifold 226. For example, the lid 219 is made of a metal such as nickel alloy and stainless steel, and is of a disk shape. The lid 219 may be configured such that an outer surface of the lid 219 is covered with a heat resistant material such as quartz (SiO₂) and silicon carbide (SiC).

A boat support 218 configured to support the boat 214 is provided on the lid 219. For example, the boat support 218 is made of a material such as quartz and SiC. The boat support 218 also functions as a heat insulator.

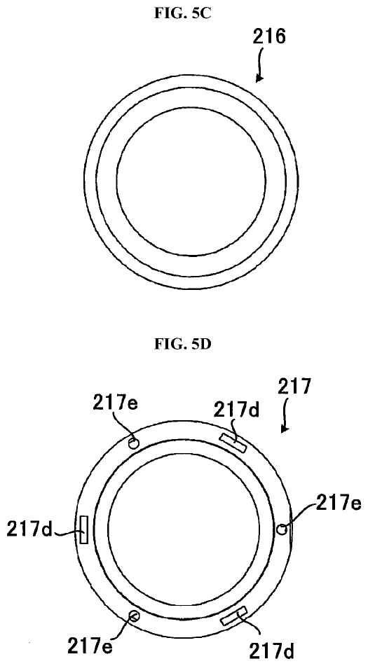

The boat 214 is provided vertically on the boat support 218. For example, the boat 214 is made of a material such as quartz and SiC. As shown in FIG. 5A, the boat 214 includes a bottom plate 217 (which will be described later) fixed to the boat support 218 and a top plate 216 (which will be described later) provided above the bottom plate 217. As shown in FIGS. 2, 5A and 7, a plurality of support columns such as support columns 215a, 215b, 215c, 215d and 215e are provided between the bottom plate 217 and the top plate 216.

The boat 214 accommodates the wafers 200 to be processed in the process chamber 201 in the inner tube 12. The wafers 200 are arranged in the horizontal orientation in the multistage manner with predetermined intervals therebetween. Further, the wafers 200 are supported in the boat 214 with their centers aligned with one another, and a stacking direction of the wafers 200 is equal to an axial direction of the reaction tube 203. That is, the centers of the wafers 200 are aligned with a central axis of the boat 214, and the central axis of the boat 214 coincides with a central axis of the reaction tube 203. The boat 214 will be described later in detail.

A rotator 267 configured to support and rotate the boat 214 is provided below the lid 219. The rotating shaft 265 of the rotator 267 is connected to the boat support 218 through the lid 219. As the rotator 267 rotates the boat 214 via the boat support 218, the wafers 200 supported by the boat 214 are rotated.

The lid 219 is capable of being elevated or lowered in the vertical direction by an elevator 115 provided outside the reaction tube 203. The elevator 115 serves as an elevating structure. As the lid 219 is elevated or lowered in the vertical direction by the elevator 115, the boat 214 is transferred (loaded) into the process chamber 201 or transferred (unloaded) out of the process chamber 201.

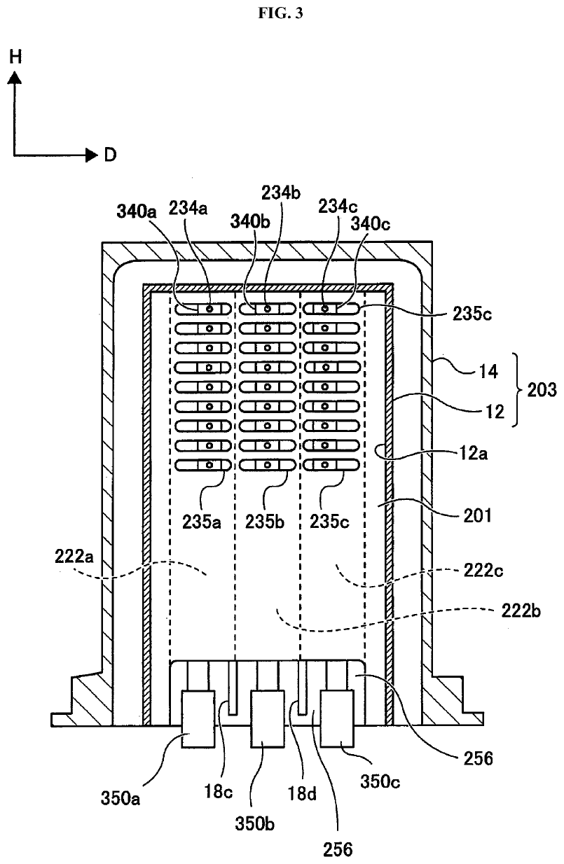

A plurality of nozzle supports such as nozzle supports 350a, 350b and 350c, which are shown in FIG. 3 and configured to support a plurality of gas nozzles (also referred to as “injectors”) such as gas nozzles 340a, 340b and 340c, respectively, are installed at an inner surface of the manifold 226. The gas nozzles 340a, 340b and 340c are configured such that gases are capable of being supplied into the process chamber 201 through each of the gas nozzles 340a, 340b and 340c. In FIG. 1, the gas nozzle 340a among the gas nozzles 340a, 340b and 340c and the nozzle support 350a among the nozzle supports 350a, 350b and 350c are shown. For example, each of the nozzle supports 350a, 350b and 350c is made of a material such as nickel alloy and stainless steel.

A plurality of gas supply pipes such as gas supply pipes 310a, 310b and 310c are connected to first ends of the nozzle supports 350a, 350b and 350c, respectively, and the gas nozzles 340a, 340b and 340c are connected to second ends of the nozzle supports 350a, 350b and 350c, respectively. The gas supply pipes 310a, 310b and 310c are configured such that the gases are capable of being supplied into the process chamber 201 through each of the gas supply pipes 310a, 310b and 310c. For example, each of the gas nozzles 340a, 340b and 340c is fabricated by forming pipes of a material such as quartz and SiC into a desired shape. The gas nozzles 340a, 340b and 340c and the gas supply pipes 310a, 310b and 310c will be described later in detail.

On the other hand, an exhaust port 230 fluidly communicating with the gap S is provided at the outer tube 14 of the reaction tube 203. The exhaust port 230 is adjacent to the lower end of the outer tube 14 and is provided below a second exhaust outlet 237 that will be described later.

An exhaust pipe 231 is provided such that a vacuum pump 246 serving as a vacuum exhauster is fluidly communicated with the exhaust port 230. A pressure sensor 245 and an APC (Automatic Pressure Controller) valve 244 are provided in the middle of the exhaust pipe 231. The pressure sensor 245 is configured to detect an inner pressure of the process chamber 201, and the APC valve 244 serves as a pressure regulator. An outlet of the vacuum pump 246 is connected to a component such as a waste gas processing apparatus (not shown). By controlling an output of the vacuum pump 246 and adjusting an opening degree of the APC valve 244, it is possible to adjust the inner pressure of the process chamber 201 to a predetermined pressure (vacuum degree).

Further, a temperature sensor (not shown) serving as a temperature detector is provided in the reaction tube 203. By adjusting an electrical power supplied to the heater 207 based on temperature information detected by the temperature sensor, it is possible to obtain a desired temperature distribution of an inner temperature of the process chamber 201.

According to the configuration of the process furnace 202 described above, the boat 214 is transferred (loaded) into the process chamber 201 while being supported by the boat support 218 in a state where the wafers 200 to be batch-processed are stacked in the boat 214 in the multistage manner. Then, the wafers 200 loaded in the process chamber 201 are heated by the heater 207 to a predetermined temperature. An apparatus provided with the process furnace 202 described above may also be referred to as a “vertical batch type apparatus”.

<Configuration of Main Components>

Subsequently, the inner tube 12, the nozzle chambers 222, the gas supply pipes 310a, 310b and 310c, the gas nozzles 340a, 340b and 340c, the boat 214, and the controller 280 will be described in detail.

<Inner Tube 12>

As shown in FIGS. 2, 3, 4A and 4B, a plurality of supply slits 235a, a plurality of supply slits 235b, a plurality of supply slits 235c and a first exhaust outlet 236 are provided on a circumferential wall of the inner tube 12. Hereinafter, a supply slit among the supply slits 235a, a supply slit among the supply slits 235b and a supply slit among the supply slits 235c may also be referred to as a “supply slit 235a”, a “supply slit 235b” and a “supply slit 235c”, respectively. Further, the supply slits 235a, the supply slits 235b and the supply slits 235c may be described based on the supply slit 235a, the supply slit 235b and the supply slit 235c. The first exhaust outlet 236 is provided on the circumferential wall of the inner tube 12 so as to face the supply slits 235a, the supply slits 235b and the supply slits 235c. The supply slits 235a, the supply slits 235b and the supply slits 235c serve as an inlet through which the gas is supplied (or introduced) into the process chamber 201, and the first exhaust outlet 236 serves as an outlet through which the gas in the process chamber 201 is discharged (or exhausted) toward the gap S. In addition, the second exhaust outlet 237 is provided on the circumferential wall of the inner tube 12 to be lower than the first exhaust outlet 236. The second exhaust outlet 237 serves as an example of a discharge outlet whose opening area is smaller than that of the first exhaust outlet 236. As described above, the supply slits 235a, the supply slits 235b, the supply slits 235c, the first exhaust outlet 236 and the second exhaust outlet 237 are provided at different locations in a circumferential direction of the inner tube 12, and the first exhaust outlet 236 and the second exhaust outlet 237 are provided so as to face the supply slits 235a, the supply slits 235b and the supply slits 235c.

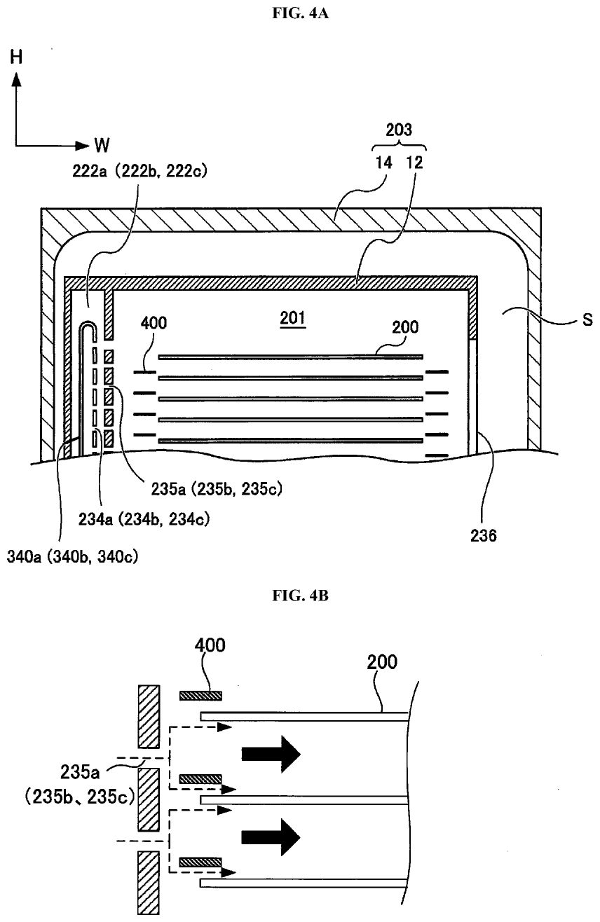

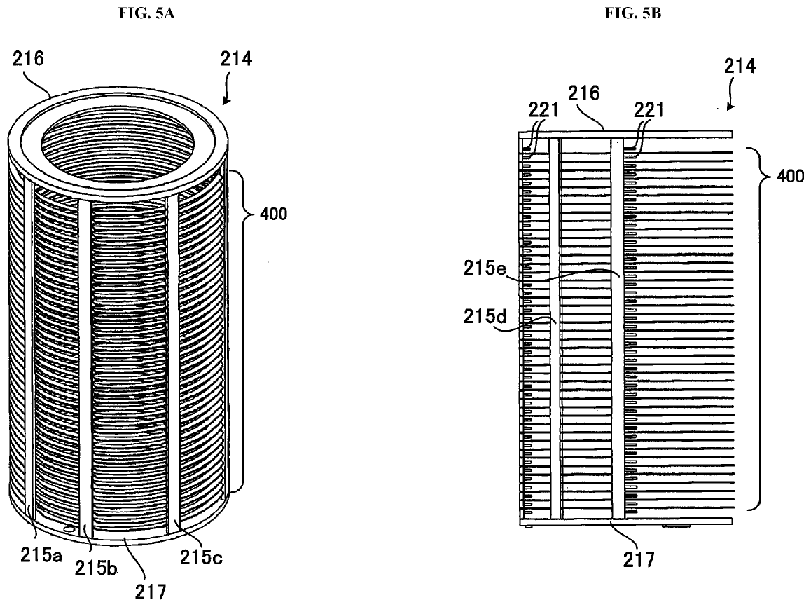

As shown in FIGS. 1 and 4A, the first exhaust outlet 236 formed at the inner tube 12 is provided at a region of the process chamber 201 where the wafers 200 are accommodated so as to face an edge (side portion) of each of the wafers 200. Hereinafter, the region where the wafers 200 are accommodated may also be referred to as a “wafer region”. In addition, the first exhaust outlet 236 is aligned in the same direction with the second exhaust port 237 when viewed from the central axis of the reaction tube 203. For example, the first exhaust outlet 236 extends from a lower end to an upper end of the wafer region in the vertical direction. Further, the first exhaust outlet 236 is fluidly in communication with the vacuum pump 246 via the exhaust port 230 such that the gas flowing over a surface of each of the wafers 200 is capable of being exhausted through the first exhaust outlet 236. The second exhaust outlet 237 is provided within a range from a position higher than an upper end of the exhaust port 230 to a position higher than a lower end of the exhaust port 230 such that an atmosphere of a lower region of the process chamber 201 is capable of being exhausted through the second exhaust outlet 237.

That is, the first exhaust outlet 236 serves as a gas exhaust outlet through which an inner atmosphere of the process chamber 201 is exhausted toward the gap S. The gas exhausted through the first exhaust outlet 236 flows substantially downward in the gap S, and is exhausted to the outside of the reaction tube 203 through the exhaust port 230. Similarly, the gas exhausted through the second exhaust outlet 237 is exhausted to the outside of the reaction tube 203 through a lower region of the gap S and the exhaust port 230.

According to the configuration of the inner tube 12 described above, the gas after flowing over the surface of each of the wafers 200 is exhausted in the shortest distance through an entirety of the gap S serving as a flow path. Thereby, it is possible to minimize a pressure loss between the first exhaust outlet 236 and the exhaust port 230. Thus, by lowering a pressure of the wafer region or by increasing a flow velocity in the wafer region, it is possible to mitigate (or reduce) the loading effect.

As shown in FIGS. 2 and 3, each of the supply slits 235a provided on the circumferential wall of the inner tube 12 is of a shape of a horizontally elongated slit while being arranged in multiple stages in the vertical direction. Further, a first nozzle chamber 222a of the nozzle chambers 222 and the process chamber 201 communicate with each other through the supply slits 235a.

Further, each of the supply slits 235b is of a shape of a horizontally elongated slit while being arranged in multiple stages in the vertical direction. The supply slits 235b are provided in parallel with the supply slits 235a, respectively. Further, a second nozzle chamber 222b of the nozzle chambers 222 and the process chamber 201 communicate with each other through the supply slits 235b.

Further, each of the supply slits 235c is of a shape of a horizontally elongated slit while being arranged in multiple stages in the vertical direction. The supply slits 235c are provided opposite to the supply slits 235a with the supply slits 235b interposed therebetween, respectively. Further, a third nozzle chamber 222c of the nozzle chambers 222 and the process chamber 201 communicate with each other through the supply slits 235c.

The supply slit 235a, the supply slit 235b and the supply slit 235c are open at substantially the same height as the wafer 200 corresponding thereto. Specifically, as shown in FIGS. 4A and 4B, the supply slits 235a, the supply slits 235b and the supply slits 235c are arranged in the vertical direction so as to face spaces between adjacent wafers among the wafers 200 supported in multiple stages by the boat 214 accommodated in the process chamber 201 and a space between an uppermost wafer among the wafers 200 and the top plate 216 of the boat 214, respectively. As a result, the gas is capable of being supplied to the wafers 200 through the supply slits 235a, the supply slits 235b and the supply slits 235c corresponding to the wafers 200 accommodated in the reaction tube 203. Thereby, it is possible to provide a gas flow parallel to the surface of each of the wafers 200.

Further, positions of the supply slits 235a, positions of the supply slits 235b and positions of the supply slits 235c are set with the intention of maximizing an amount of the gas reaching the surfaces of the wafers 200 corresponding thereto in cooperation with a plurality of separation rings 400 described later. Specifically, as shown in FIG. 4B, the supply slits 235a, the supply slits 235b and the supply slits 235c are positioned such that a lower end of the supply slit 235a, a lower end of the supply slit 235b and a lower end of the supply slit 235c are located higher than an upper surface of the wafer 200 corresponding thereto and higher than an upper surface of a separation ring (among the separation rings 400) located directly above the wafer 200 corresponding thereto, and such that an upper end of the supply slit 235a, an upper end of the supply slit 235b and an upper end of the supply slit 235c are located lower than a lower surface of a wafer (among the wafers 200) located directly above the wafer 200 corresponding thereto. In such an arrangement, most of the gas flows between the wafer 200 corresponding thereto and the separation ring located directly above the wafer 200 corresponding thereto, and between the separation ring located directly above the wafer 200 corresponding thereto and the lower surface of the wafer located directly above the wafer 200 corresponding thereto.

Supply slits serving as the supply slit 235a, the supply slit 235b and the supply slit 235c may be further provided between a lowermost wafer among the wafers 200 capable of being accommodated in the boat 214 and the bottom plate 217 of the boat 214. In such a case, the number of the supply slits 235a (the number of the supply slits 235b and the number of the supply slits 235c) arranged in the vertical direction is one more than the number of the wafers 200.

Further, preferably, when lengths of the supply slits 235a, lengths of the supply slits 235b and lengths of the supply slits 235c in the circumferential direction of the inner tube 12 are set substantially the same as lengths of the nozzle chambers 222a, 222b and 222c in the circumferential direction, respectively, it is possible to improve a gas supply efficiency.

Edge portions (such as four corners) of each of the supply slits 235a, the supply slits 235b and the supply slits 235c are formed as smooth curves. By curving the edge portions by a process such as a rounding process (R process), it is possible to suppress a stagnation of the gas at the edge portions and to suppress a formation of a film on the edge portions. It is also possible to prevent the film from being peeled off even when the film is formed on the edge portions.

Further, an opening 256 is provided at a lower end of an inner circumferential surface 12a of the inner tube 12 where the supply slits 235a, the supply slits 235b and the supply slits 235c are provided. The opening 256 is used to install the gas nozzles 340a, 340b and 340c in corresponding nozzle chambers 222a, 222b and 222c of the nozzle chambers 222.

<Nozzle Chambers 222>

As shown in FIG. 2, the nozzle chambers 222 are provided in the gap S between an outer circumferential surface 12c of the inner tube 12 and an inner circumferential surface 14a of the outer tube 14. The nozzle chambers 222 includes the first nozzle chamber 222a extending in the vertical direction, the second nozzle chamber 222b extending in the vertical direction and the third nozzle chamber 222c extending in the vertical direction. The first nozzle chamber 222a, the second nozzle chamber 222b and the third nozzle chamber 222c are disposed in this order along a circumferential direction of the process chamber 201. Each of the first nozzle chamber 222a, the second nozzle chamber 222b and the third nozzle chamber 222c is an example of a supply chamber (also referred to as a “supply buffer”).

Specifically, the nozzle chambers 222 are provided in a space defined by a first partition 18a, a second partition 18b, an arc-shaped outer wall 20 and the inner tube 12. The first partition 18a and the second partition 18b extend in parallel from the outer circumferential surface 12c of the inner tube 12 toward the outer tube 14. The arc-shaped outer wall 20 is configured to connect a front end of the first partition 18a and a front end of the second partition 18b.

In addition, a third partition 18c and a fourth partition 18d are provided in the nozzle chambers 222. The third partition 18c and the fourth partition 18d extend from the outer circumferential surface 12c of the inner tube 12 toward the outer wall 20. The third partition 18c and the fourth partition 18d are located in this order between the first partition 18a and the second partition 18b. The outer wall 20 is separated from the outer tube 14. Further, a front end of the third partition 18c and a front end of the fourth partition 18d reach the outer wall 20. The first through fourth partitions 18a through 18d and the outer wall 20 are examples of a partition structure.

The first through fourth partitions 18a through 18d and the outer wall 20 extend vertically from a ceiling portion of the nozzle chambers 222 to the lower end of the reaction tube 203. Specifically, as shown in FIG. 3, a lower end of the third partition 18c and a lower end of the fourth partition 18d extend to from an upper edge of the opening 256 to a lower region of the opening 256.

As shown in FIG. 2, the first nozzle chamber 222a is defined by being surrounded by the inner tube 12, the first partition 18a, the third partition 18c and the outer wall 20, and the second nozzle chamber 222b is defined by being surrounded by the inner tube 12, the third partition 18c, the fourth partition 18d and the outer wall 20. Further, the third nozzle chamber 222c is defined by being surrounded by the inner tube 12, the fourth partition 18d, the second partition 18b and the outer wall 20. Thereby, the first nozzle chamber 222a, the second nozzle chamber 222b and the third nozzle chamber 222c, whose lower ends are open and whose upper ends are closed by a flat wall constituting the ceiling of the inner tube 12, extend in the vertical direction. That is, the first nozzle chamber 222a, the second nozzle chamber 222b and the third nozzle chamber 222c are provided with ceilings, respectively.

As described above, as shown in FIG. 3, the supply slits 235a through which the first nozzle chamber 222a is communicated with the process chamber 201 are arranged on the circumferential wall of the inner tube 12 in multiple stages in the vertical direction. Further, the supply slits 235b through which the second nozzle chamber 222b is communicated with the process chamber 201 are arranged on the circumferential wall of the inner tube 12 in multiple stages in the vertical direction, and the supply slits 235c through which the third nozzle chamber 222c is communicated with the process chamber 201 are arranged on the circumferential wall of the inner tube 12 in multiple stages in the vertical direction.

<Gas Nozzles 340a, 340b and 340c>

The gas nozzles 340a, 340b and 340c extend in the vertical direction. As shown in FIG. 2, the gas nozzles 340a, 340b and 340c are provided in the nozzle chambers 222a, 222b and 222c, respectively. Specifically, the gas nozzle 340a communicating with the gas supply pipe 310a is disposed in the first nozzle chamber 222a. The gas nozzle 340b communicating with the gas supply pipe 310b is disposed in the second nozzle chamber 222b, and the gas nozzle 340c communicating with the gas supply pipe 310c is disposed in the third nozzle chamber 222c.

When viewed from above, the gas nozzle 340b is interposed between the gas nozzle 340a and the gas nozzle 340c in the circumferential direction of the process chamber 201. Further, the gas nozzle 340a and the gas nozzle 340b are partitioned by the third partition 18c, and the gas nozzle 340b and the gas nozzle 340c are partitioned by the fourth partition 18d. As a result, it is possible to prevent the gases from being mixed with one another among the nozzle chambers 222.

For example, each of the gas nozzles 340a, 340b and 340c is configured as an I-shaped long nozzle. As shown in FIG. 3, a plurality of ejection holes 234a, a plurality of ejection holes 234b and a plurality of ejection holes 234c through which the gas is ejected are provided on circumferential surfaces of the gas nozzles 340a, 340b and 340c, respectively, so as to face the supply slits 235a, the supply slits 235b and the supply slits 235c, respectively. Hereinafter, an ejection hole among the ejection holes 234a, an ejection hole among the ejection holes 234b and an ejection hole among the ejection holes 234c may also be referred to as an “ejection hole 234a”, an “ejection hole 234b” and an “ejection hole 234c”, respectively. Specifically, it is preferable that the ejection holes 234a of the gas nozzle 340a, the ejection holes 234b of the gas nozzle 340b and the ejection holes 234c of the gas nozzle 340c face central portions of the supply slits 235a, the supply slits 235b and the supply slits 235c, respectively, in the vertical direction such that each of the ejection holes 234a corresponds to each of the supply slits 235a, each of the ejection holes 234b corresponds to each of the supply slits 235b and each of the ejection holes 234c corresponds to each of the supply slits 235c. Alternatively, as shown in FIGS. 4A and 4B, the ejection holes 234a, the ejection holes 234b and the ejection holes 234c may be located at height positions such that a horizontal line passing through a center of the ejection hole 234a (the ejection hole 234b or the ejection hole 234c) is located between the upper surface of the wafer 200 corresponding thereto and the lower surface of the wafer provided directly above the wafer 200 corresponding thereto and between the upper surface of the separation ring (among the separation rings 400) provided directly above the wafer 200 corresponding thereto and the lower surface of the wafer provided directly above the wafer 200 corresponding thereto.

According to the present embodiments, each of the ejection holes 234a (the ejection holes 234b and the ejection holes 234c) is of a pin-hole shape. Further, a size in the vertical direction (that is, a diameter) of each of the ejection holes 234a (the ejection holes 234b and the ejection holes 234c) is smaller than a size of each of the supply slits 235a (the supply slits 235b and the supply slits 235c) in the height direction corresponding thereto. In addition, the gas ejected through the ejection holes 234a of the gas nozzle 340a (the gas ejected through the ejection holes 234b of the gas nozzle 340b and the gas ejected through the ejection holes 234c of the gas nozzle 340c) is directed to a center of the process chamber 201 when viewed from above, and is directed to the spaces between the adjacent wafers among the wafers 200, a space above an upper surface of the uppermost wafer among the wafers 200 or a space below a lower surface of the lowermost wafer among the wafers 200 when viewed from a side as shown in FIG. 4A.

As described above, a range in which the ejection holes 234a, the ejection holes 234b and the ejection holes 234c are arranged in the vertical direction covers a range in which the wafers 200 are arranged in the vertical direction. In addition, ejection directions in which the gases are ejected through the ejection holes 234a, the ejection holes 234b and the ejection holes 234c are the same.

According to the configurations described above, the gases ejected via the ejection holes 234a of the gas nozzle 340a, the ejection holes 234b of the gas nozzle 340b and the ejection holes 234c of the gas nozzle 340c are supplied into the process chamber 201 through the supply slits 235a, the supply slits 235b and the supply slits 235c provided at the inner tube 12. The inner tube 12 constitutes front walls of the nozzle chambers 222a, 222b and 222c. Then, the gases supplied into the process chamber 201 flow along upper and lower surfaces of each of the wafers 200 in a direction parallel thereto.

<Gas Supply Pipes 310a, 310b and 310c>

As shown in FIG. 1, the gas supply pipe 310a communicates with the gas nozzle 340a through the nozzle support 350a, and the gas supply pipe 310b communicates with the gas nozzle 340b through the nozzle support 350b. Further, the gas supply pipe 310c communicates with the gas nozzle 340c through the nozzle support 350c.

A source gas supply source 360a capable of supplying a first source gas (also referred to as a “reactive gas”) serving as one of the process gases, a mass flow controller (MFC) 320a serving as an example of a flow rate controller and a valve 330a serving as an opening/closing valve are sequentially provided at the gas supply pipe 310a in this order from an upstream side toward a downstream side of the gas supply pipe 310a in a gas flow direction.

A source gas supply source 360b capable of supplying a second source gas serving as one of the process gases, a mass flow controller (MFC) 320b and a valve 330b are sequentially provided at the gas supply pipe 310b in this order from an upstream side toward a downstream side of the gas supply pipe 310b in the gas flow direction.

An inert gas supply source 360c capable of supplying an inert gas serving as one of the process gases, a mass flow controller (MFC) 320c and a valve 330c are sequentially provided at the gas supply pipe 310c in this order from an upstream side toward a downstream side of the gas supply pipe 310c in the gas flow direction.

A gas supply pipe 310d through which the inert gas is supplied is connected to the gas supply pipe 310a at a downstream side of the valve 330a. An inert gas supply source 360d capable of supplying the inert gas serving as one of the process gases, a mass flow controller (MFC) 320d and a valve 330d are sequentially provided at the gas supply pipe 310d in this order from an upstream side toward a downstream side of the gas supply pipe 310d in the gas flow direction.

Further, a gas supply pipe 310e through which the inert gas is supplied is connected to the gas supply pipe 310b at a downstream side of the valve 330b. An inert gas supply source 360e capable of supplying the inert gas serving as one of the process gases, a mass flow controller (MFC) 320e and a valve 330e are sequentially provided at the gas supply pipe 310e in this order from an upstream side toward a downstream side of the gas supply pipe 310e in the gas flow direction. Further, the inert gas supply sources 360c, 360d and 360e capable of supplying the inert gas may be connected to a common supply source. Hereinafter, the process gases may be simply collectively or individually referred to as a “process gas”.

For example, as the first source gas supplied through the gas supply pipe 310a, ammonia (NH₃) gas may be used. For example, as the second source gas supplied through the gas supply pipe 310b, a silicon (Si) source gas may be used. For example, as the inert gas supplied through each of the gas supply pipes 310c, 310d and 310e, nitrogen (N₂) gas may be used.

A gas supply structure configured to supply the gases in the direction parallel to the surface of the wafer 200 and to eject the gases toward the central axis of the boat 214 is constituted by components such as the supply pipes 310a, 310b and 310c, the gas nozzles 340a, 340b and 340c, the ejection holes 234a, the ejection holes 234b, the ejection holes 234c, the supply slits 235a, the supply slits 235b and the supply slits 235c. Further, a gas exhaust structure configured to exhaust the gas flowing on the surface of the wafer 200 is constituted by components such as the first exhaust outlet 236, the second exhaust outlet 237, the exhaust port 230, the exhaust pipe 231 and the vacuum pump 246.

<Boat 214>

Subsequently, the boat 214 will be described in detail with reference to FIGS. 5A through 9C. For example, the boat 214 includes the bottom plate 217 of a disk shape, the top plate 216 of a disk shape and the plurality of support columns (for example, five support columns according to the present embodiments, that is, the support columns 215a, 215b, 215c, 215d and 215e) connecting and fixing the bottom plate 217 and the top plate 216 in the vertical direction. At the support columns 215a through 215e between the bottom plate 217 and the top plate 216, the plurality of separation rings 400 serving as a plurality of annular structures are arranged in a substantially horizontal orientation and in a multistage manner along the vertical direction. Further, a plurality of support pins 221 serving as a plurality of support structures are provided between adjacent separation rings among the separation rings 400. The support pins 221 are provided so as to support the wafers 200 substantially horizontally. The support pins 221 extend toward a radially inward direction from each of the support columns 215a, 215c and 215e. The wafer 200 is placed on the support pins 221 corresponding to the wafer 200 at a position substantially halfway between an upper separation ring (among the separation rings 400) corresponding to the support pins 221 and a lower separation ring (among the separation rings 400) corresponding to the support pins 221.

A plurality of bolt mounting holes (for example, three bolt mounting holes according to the present embodiments) 217e through which the boat 214 is fixed to the boat support 218 are provided at the bottom plate 217. In addition, a plurality of leg structures of a rectangular shape (for example, three leg structures according to the present embodiments) 217d are provided on a bottom surface of the bottom plate 217 such that the boat 214 is capable of being vertically installed on the boat support 218 by using the leg structures 217d.

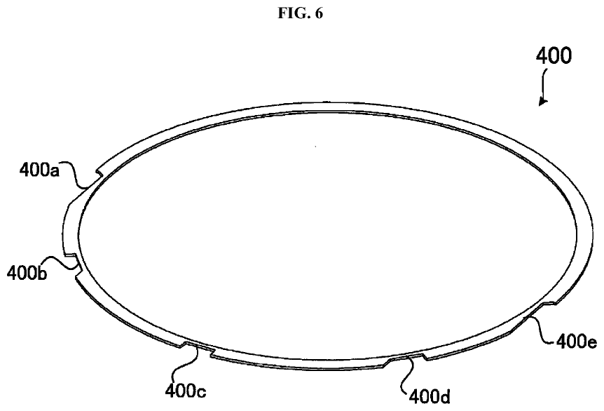

Hereinafter, a separation ring among the separation rings 400 may also be referred to as a “separation ring 400”. Since configurations of the separation rings 400 are substantially the same, the separation rings 400 will be described based on the separation ring 400. As shown in FIG. 6, the separation ring 400 is a structure of a flat plate of an annular shape. For example, the separation ring 400 is made of a material such as quartz. Further, a plurality of notches (for example, five notches according to the present embodiments, that is, notches 400a, 400b, 400c, 400d and 400e) are formed at an outer circumferential surface of the separation ring 400. The notches 400a through 400e are provided so as to prevent the separation ring 400 from contacting the support columns 215a through 215e, respectively. The notches 400a through 400e are in contact with the support columns 215a through 215e, respectively.

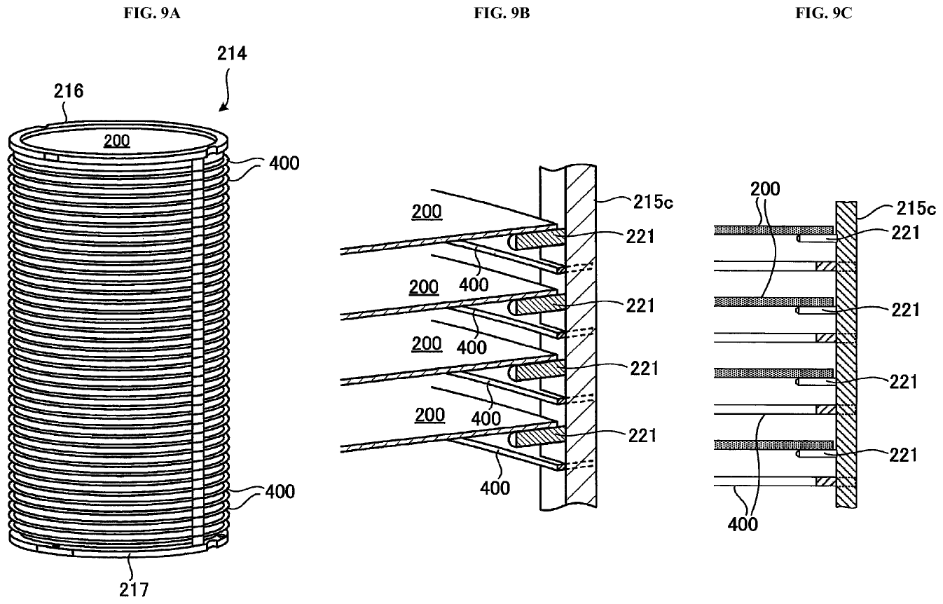

A width and a thickness of the separation ring 400 are constant except for its contact portions with the support columns 215a through 215e. For example, an inner diameter of the separation ring 400 is 296 mm, which is equal to or smaller than an outer diameter (for example, 300 mm) of the wafer 200 (see FIGS. 9B and 9C). Further, for example, an outer diameter of the separation ring 400 is 315 mm, which is larger than the outer diameter of the wafer 200 (see FIGS. 9B and 9C). According to the present embodiments, the width of the separation ring 400 is a difference between the outer diameter of the separation ring 400 and the inner diameter of the separation ring 400. For example, the outer diameter of the separation ring 400 is within a range from 280 mm to 300 mm. Further, the width of the separation ring 400 is within a range from 5 mm to 12 mm. In addition, the thickness of the separation ring 400 is set to be a thickness that does not obstruct a flow of the gas and does not pose a problem in terms of strength. For example, the thickness of the separation ring 400 is within a range from 1 mm to 2 mm. More specifically, for example, the thickness of the separation ring 400 is 1.5 mm.

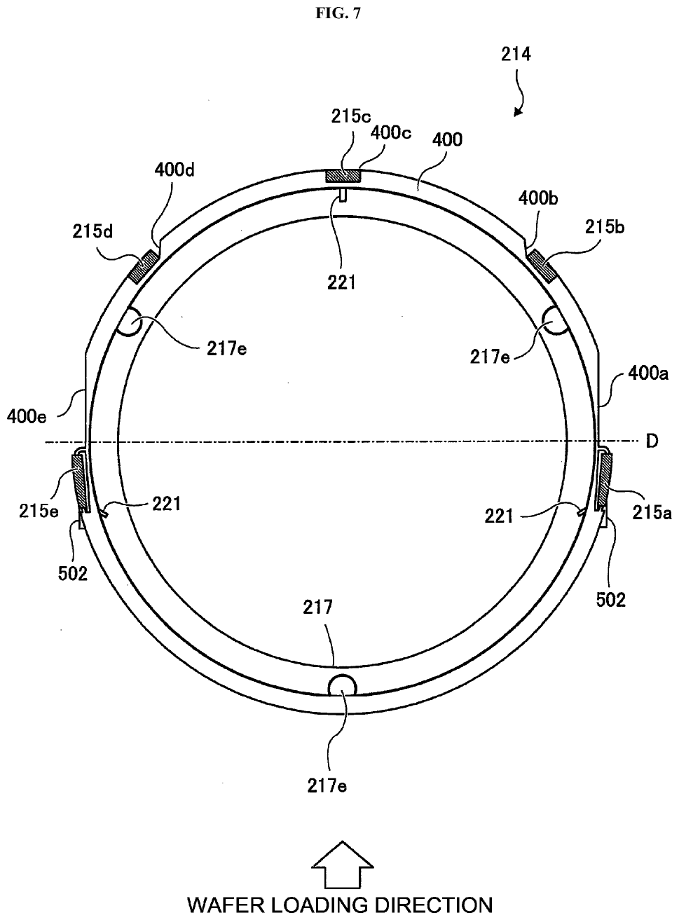

For example, as shown in FIG. 6, the notches 400a through 400e are provided at an outer circumference of the separation ring 400, and the number of the notches 400a through 400e is the same as the number of the support columns 215a through 215e (that is, five notches 400a through 400e and five support columns 215a through 215 are provided according to the present embodiments). Further, as shown in FIG. 7, the notches 400a through 400e extend from its front end wherein “front” is defined along a loading direction of the wafer 200 (also referred to as a “front side in an inserting direction of the separation ring 400”) to its rear end wherein “rear” is defined along the loading direction of the wafer 200. Hereinafter, the loading direction of the wafer 200 may also be simply referred to as a “wafer loading direction”. Thereby, it is possible to insert the separation ring 400 into the boat 214 in a substantially horizontal direction. Hereinafter, the terms “front” and “rear” are defined along the wafer loading direction as in this paragraph.

Specifically, the notch 400c (among the notches 400a through 400e) provided at a rear side in the inserting direction of the separation ring 400 is of such a shape that the support column 215c corresponding to the notch 400c protrudes in the inserting direction of the separation ring 400 to be fitted into the notch 400c. Further, a front portion of each of the notch 400b and the notch 400d in the inserting direction of the separation ring 400 is of such a shape that each of the support column 215b (corresponding to the notch 400b) and the support column 215d (corresponding to the notch 400d) protrudes in a radial direction of the separation ring 400 to be fitted into the notch 400b or 400d corresponding thereto. In addition, a rear portion of each of the notch 400b and the notch 400d extends along the wafer loading direction. Further, as shown in FIG. 7, a front portion of each of the notch 400a and the notch 400e (which are provided at a front side in the inserting direction of the separation ring 400) is of such a shape that each of the support column 215a corresponding to the notch 400a and the support column 215e corresponding to the notch 400e protrudes in the radial direction of the separation ring 400 to be fitted into the notch 400a or 400e corresponding thereto. In addition, each of the notch 400a and the notch 400e extends from a front side to a rear side of the separation ring 400 along the wafer loading direction.

That is, as shown in FIG. 7, the notches 400a and 400e are formed substantially in parallel to the wafer loading direction when the wafer 200 is transferred to the support pins 221, and two support columns (that is the support column 215a and the support column 215e provided at the front side in the inserting direction of the separation ring 400) are arranged in the notches 400a and 400e, respectively.

Each of the support columns 215a through 215e is a polygonal column of a rectangular shape that is longer in a circumferential direction of the separation ring 400 and shorter in the radial direction (width direction) of the separation ring 400. Both circumferential side surfaces (i.e., side surfaces that face toward the circumferential direction of the separation ring 400) of each of the support columns 215a through 215e are substantially perpendicular to the circumferential direction of the separation ring 400. That is, normal lines of both the circumferential side surfaces of each of the support columns 215a through 215e are respectively oriented substantially in the circumferential direction of the separation ring 400. Further, a cross-section of each of the support columns 215a through 215e is of an asymmetrical shape that is longer in the circumferential direction of the separation ring 400 than in the width direction of the separation ring 400. The two support columns 215a and 215e at the front side are provided such that their surfaces facing an inner periphery of the separation ring 400 are substantially parallel to the wafer loading direction. Between adjacent separation rings among the separation rings 400, the support pins 221 are provided on at least three support columns (such as the support columns 215a, 215c and 215e) among the support columns 215a through 215e. Further, an outer peripheral surface of each of the support columns 215a through 215e is of a shape corresponding to outer peripheral surfaces of the separation rings 400. In other words, a width of each of the support columns 215a through 215e is narrower than the width of the separation ring 400, and as shown in FIG. 7, each of the support columns 215a through 215e is provided along an outer edge of the separation ring 400. Further, the plurality of support columns (that is, five support columns according to the present embodiments), more specifically, the support columns 215a through 215e are configured to support the separation rings 400.

As shown in FIG. 7, the separation ring 400 is integrated with the boat 214 as a single body by welding the notches 400a through 400e and the support columns 215a through 215e, respectively, in a state where the notches 400a through 400e are in contact with the support columns 215a through 215e, respectively, or in a state where the notches 400a through 400e are located close to the support columns 215a through 215e, respectively. For example, the support columns 215a through 215e are spot welded with notches 400a through 400e, respectively.

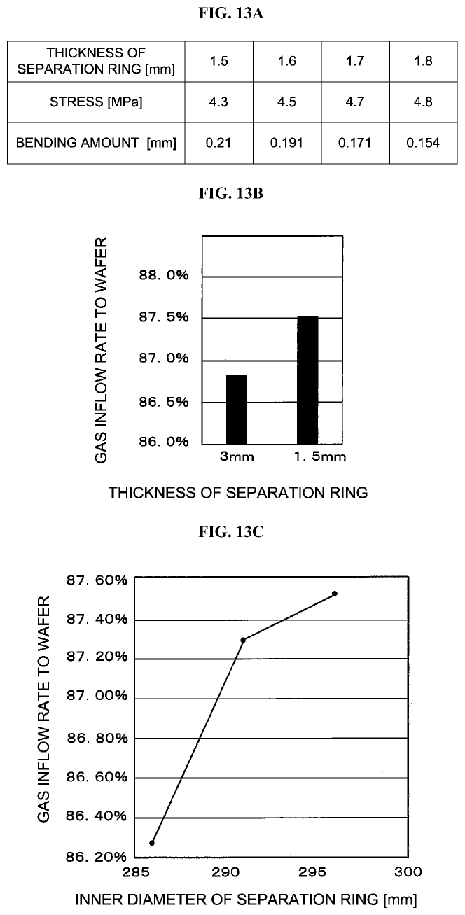

Although details will be described later, as shown in FIG. 13A, by increasing the thickness of the separation ring 400, it is possible to prevent (or suppress) the separation ring 400 from being bent downward (drooping or sagging). However, it is confirmed that a stress at fixing portions between the separation ring 400 and the support columns 215a through 215e is increased.

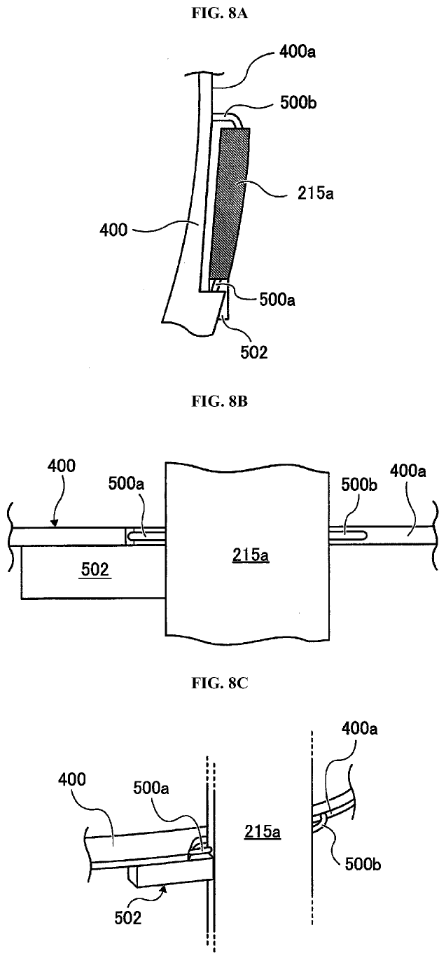

Therefore, in the boat 214 according to the embodiments of the present disclosure, as shown in FIGS. 8A through 8C, the support columns 215a through 215e on the front side are connected with the separation ring 400 by being welded and fixed to the boat 214 with rods 500a and 500b serving as connecting structures interposed therebetween. Thereby, it is possible to absorb the deformation in a direction perpendicular to an extending direction of the rods 500a and 500b in the form of a bending moment corresponding to the deformation. That is, by bending the rods 500a and 500b, it is possible to absorb the deformation of the fixing portions between the separation ring 400 and the support columns 215a through 215e as well as their peripheral portions, and it is also possible to mitigate (or reduce) the stress in the fixing portions between the separation ring 400 and the support columns 215a through 215e. In other words, instead of directly welding the separation ring 400 with the support columns 215a through 215e, the support columns 215a through 215e are welded with the separation ring 400 via the rods 500a and 500b of a thin shape such that the stress is not concentrated on the fixing portions between the separation ring 400 and the support columns 215a through 215e, thereby making it possible to increase a strength against the stress.

Specifically, as described above, first ends of the rods 500a and 500b are welded to surfaces of the support columns 215a and 215e at both circumferential ends, respectively, and second ends of the rods 500a and 500b are welded to the separation ring 400. That is, the two rods 500a and 500b are provided between the separation ring 400 and the support column 215a, and the two rods 500a and 500b are provided between the separation ring 400 and the support column 215e. The separation ring 400 and the support column 215a are connected via the two rods 500a and 500b, and similarly, the separation ring 400 and the support column 215e are connected via the two rods 500a and 500b.

For example, with respect to each of the notches 400a and 400e on the front side, each of the support columns 215a and 215e on the front side is welded and fixed to the separation ring 400 via the rods 500a and 500b. That is, each of the separation rings 400 and the support columns 215a and 215e are connected by the rods 500a and 500b.

Each of the rods 500a and 500b is of a round bar shape whose diameter is equal to or less than the thickness of the separation ring 400. Further, each of the rods 500a and 500b is made of the same material as the separation ring 400 and the support columns 215a through 215e. For example, each of the rods 500a and 500b is made of a material such as quartz. Further, the rod 500a is provided in a gap between a surface of the separation ring 400 on which the notch 400a is provided and the side surface of the support column 215a corresponding thereto, and the rod 500b is provided in a gap between a surface of the separation ring 400 on which the notch 400e is provided and the side surface of the support column 215e corresponding thereto. The rods 500a and 500b are welded to the separation ring 400 and the support columns 215a and 215e on the front side.

The rod 500a is of a linear shape, and is welded and fixed to a surface of the notch 400a substantially parallel to a width direction of the notch 400a (a surface substantially perpendicular to the wafer loading direction) and a side surface of the support column 215a corresponding thereto. Further, the rod 500b is of a curved shape, and is welded and fixed to a surface of the notch 400a substantially parallel to the wafer loading direction and the other side surface of the support column 215a corresponding thereto. Similarly, the rod 500a is welded and fixed to a surface of the notch 400e substantially parallel to a width direction of the notch 400e and a side surface of the support column 215e corresponding thereto, and the rod 500b is welded and fixed to a surface of the notch 400e substantially parallel to the wafer loading direction and the other side surface of the support column 215e corresponding thereto. It is possible to absorb the deformation in the direction perpendicular to the extending direction of each of the rods 500a and 500b in the form of the bending moment by using the rods 500a and 500b. That is, by bending the rods 500a and 500b, it is possible to absorb the deformation in the up-and-down direction (vertical direction) of the substrate processing apparatus 10, the width direction (horizontal direction) of the substrate processing apparatus 10, and the depth direction (another horizontal direction) of the substrate processing apparatus 10. In other words, by using the rod 500b whose one side is curved, the rods 500a and 500b can absorb the deformation due to the stress. Therefore, it is possible to mitigate (or reduce) the stress and also possible to prevent a damage due to the stress as compared with a case where the separation ring 400 and the support columns 215a and 215e are directly welded to one another.

Further, as shown in FIG. 7, the support columns 215a and 215e configured to fix the separation ring 400 on the front side are located outside a region in which the wafers 200 are transferred (hereinafter, also referred to as a “wafer transfer region”) and at positions displaced forward from a center axis D of the boat 214 by 10% or more of the diameter of the wafer 200 (for example, 32 mm). As a result, by suppressing the bending (drooping or sagging) of the separation ring 400, it is possible to reduce a bending amount (a drooping amount or a sagging amount) of the separation ring 400, and it is also possible to reduce the stress in the fixing portions between the separation ring 400 and the support columns 215a through 215e.

Two support columns among the support columns 215a through 215e, which is the support columns 215a and 215e located on the front side, are provided with a plurality of pedestals 502 extending forward from the support columns 215a and 215e along a direction opposite to the wafer loading direction, respectively. The pedestals 502 are configured to support the separation ring 400 from thereunder. When the separation ring 400 is placed on the pedestals 502, by further suppressing the bending (drooping or sagging) of the separation ring 400, it is possible to further reduce the bending amount (the drooping amount or the sagging amount) of the separation ring 400, and it is also possible to reduce the stress in the fixing portions (welded portions) between the separation ring 400 and the rods 500a and 500b and in the fixing portions (welded portions) between the rods 500a and 500b and the support columns 215a and 215e. When the bending amount (the drooping amount or the sagging amount), a residual stress and the like can be sufficiently reduced without providing the pedestals 502, the pedestals 502 may be omitted.

Further, each component described above may be individually fire-polished before being integrated into a single body. For example, when the separation ring 400 and the support columns 215a through 215e are directly welded, a residual stress and a thermal stress of the welding may be present due to a thermal deformation caused by an expansion or contraction in the welded portions. By welding the separation ring 400 and the support columns 215a and 215e via the rods 500a and 500b of a round bar shape whose diameter is equal to or less than the thickness of the separation ring 400, as compared with a case where the welding is not performed via the rods 500a and 500b, it is possible to reduce the thermal deformation in the welded portions, and it is also possible to reduce the residual stress and the thermal stress of the welding. In addition, it is also possible to similarly reduce a thermal stress when a temperature of the boat 214 changes in the process chamber 201. Further, each of the rods 500a and 500b may be of a bar shape whose cross-section is elliptical. In such a case, a minor axis of the elliptical cross-section of each of the rods 500a and 500b may be equal to or less than the thickness of the separation ring 400.

Further, the separation rings 400 are arranged in the process chamber 201 on a plane perpendicular to the rotating shaft 265 in a manner concentric with the rotating shaft 265, and with predetermined intervals (pitch) therebetween. The separation rings 400 are arranged with and fixed to two or more of the support columns 215a through 215e. That is, centers of the separation rings 400 are aligned with the central axis of the boat 214, and the central axis of the boat 214 coincides with the central axis of the reaction tube 203 and the rotating shaft 265. That is, the separation rings 400 are supported by the support columns 215a through 215e of the boat 214 in a state where the separation rings 400 are arranged in a horizontal orientation in a multistage manner with the predetermined intervals therebetween. Further, the separation rings 400 are arranged with their centers aligned with one another, and a stacking direction of the separation rings 400 is equal to the axial direction of the reaction tube 203.

Further, a radius of the separation ring 400 is the same as a maximum distance from the central axis of each of the support columns 215a through 215e. When the notches 400a through 400e are brought into contact with the support columns 215a through 215e, respectively, an outer surface of the separation ring 400 and outer surfaces of the support columns 215a through 215e are configured to be continuous with each other. Thereby, it is possible to substantially fill (or minimize) a gap (or a space) between an inner surface of the reaction tube 203 and the wafers 200 without reducing a clearance between the boat 214 and the reaction tube 203.

As shown in FIG. 7, the support pins 221 extend substantially horizontally toward the radially inward direction from each of at least three support columns among the support columns 215a through 215e. For example, the support pins 221 are provided on the support column 215c on the rear side in the inserting direction of the separation ring 400 and the two support columns 215a and 215e on the front side in the inserting direction of the separation ring 400. The support pins 221 provided on the support columns 215a and 215e on the front side in the inserting direction of the separation ring 400 are configured to support the center of gravity of each of the wafers 200. Thus, the support pins 221 provided on the support columns 215a and 215e are projected obliquely in a direction toward where the support columns 215a through 215e are not provided. In other words, the support pins 221 are projected in an obliquely forward direction in the boat 214. The support pins 221 may be provided on the side surfaces of the support columns 215a and 215e on the front side in the inserting direction of the separation ring 400. Further, the side surfaces of the support column 215a and 215e may be obliquely oriented in an extending direction of the support pins 221 corresponding thereto. Further, the support pins 221 are provided on each of at least three support columns (for example, the support columns 215a, 215c and 215e) in a multistage manner with predetermined intervals (pitch) therebetween. Thereby, the wafers 200 can be placed on the support pins 221 substantially halfway between the separation rings 400 at the predetermined pitch. An outer diameter of each of the support pins 221 can be set to be smaller than a maximum width of each of the support columns 215a, 215c and 215e and to be greater than the thickness of the separation ring 400.

That is, the three support pins 221 support the wafers 200 substantially horizontally at positions between adjacent separation rings among the separation rings 400, and support the wafers 200 with the predetermined pitch between adjacent separation rings among the separation rings 400. The separation ring 400 is provided in a vicinity of a middle portion between the wafers 200 stacked along the stacking direction and the lower ends of the supply slits 235a, the supply slits 235b and the supply slits 235c. Thereby, a space through which an end effector transfers the wafer 200 is inserted can be secured below the wafer 200, and a space through which the wafer 200 is picked up and transferred can be secured above the wafer 200.

As described above, the separation ring 400 is of an annular shape, and a central portion of the separation ring 400 is open (that is, a central opening is provided at the separation ring 400). That is, the separation ring 400 is configured such that a space between the wafer 200 and its adjacent wafer (among the wafers 200) is not partitioned to thereby prevent the wafer 200 from being completely separated from its adjacent wafer (among the wafers 200). As a result, since a height of a flow path at the center of the wafer 200 where a thickness of the film is thin can be raised up to a gap between the wafer 200 and its adjacent wafer, it is possible to prevent a decrease in the flow velocity and it is also possible to supply an unreacted gas through the central opening of the separation ring 400. That is, as shown in FIG. 4B, the gas flowing through the supply slits 235a, the supply slits 235b and the supply slits 235c corresponding to the wafer 200 is divided into two streams flowing above and below the separation ring 400 directly above the wafer 200, and flows into the central opening to merge. With such a configuration, it is possible to increase an amount of the process gas flowing between the adjacent wafers among the wafers 200, which is supplied through the supply slits 235a, the supply slits 235b and the supply slits 235c. Thereby, it is also possible to increase a gas inflow rate which is a rate at which the process gas supplied from the supply slits 235a, the supply slits 235b and the supply slits 235c flows between the adjacent wafers.

<Controller 280>

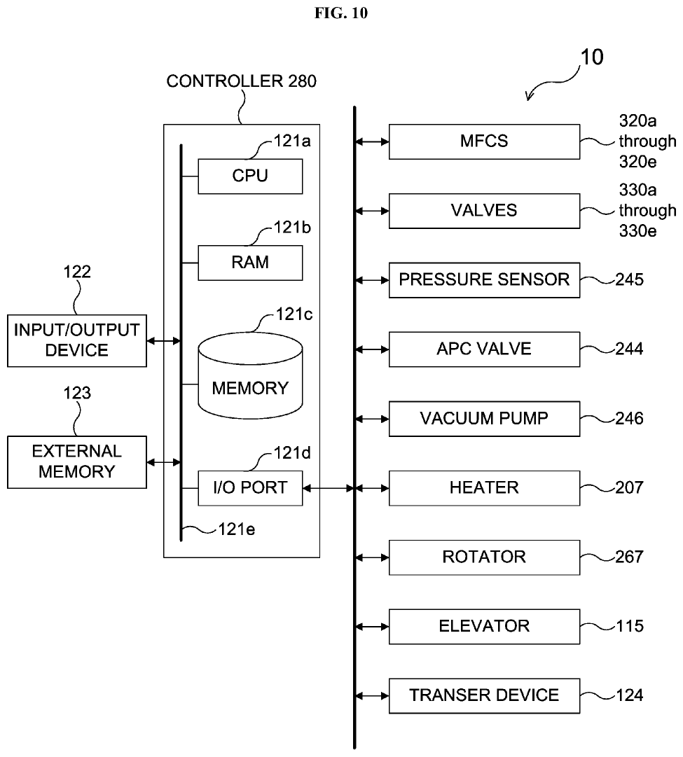

FIG. 10 is a block diagram schematically illustrating a configuration of the controller 280 of the substrate processing apparatus 10 and related components of the substrate processing apparatus 10. The controller 280 serving as a control apparatus (control structure) is constituted by a computer including a CPU (Central Processing Unit) 121a, a RAM (Random Access Memory) 121b, a memory 121c and an I/O port 121d.

The RAM 121b, the memory 121c and the I/O port 121d may exchange data with the CPU 121a through an internal bus 121e. For example, an input/output device 122 constituted by components such as a touch panel is connected to the controller 280.

For example, the memory 121c is configured by components such as a flash memory and HDD (Hard Disk Drive). A control program for controlling the operation of the substrate processing apparatus 10 and a process recipe containing information on sequences and conditions of a substrate processing described later may be readably stored in the memory 121c.

The process recipe is obtained by combining steps of the substrate processing described later such that the controller 280 can execute the steps to acquire a predetermined result, and functions as a program. Hereinafter, the process recipe and the control program may be collectively or individually referred to as a “program”.

In the present specification, the term “program” may indicate the process recipe alone, may indicate the control program alone, or may indicate both of the process recipe and the control program. The RAM 121b functions as a memory area (work area) where a program or data read by the CPU 121a is temporarily stored.

The I/O port 121d is connected to the above-described components such as the MFCs 320a through 320e, the valves 330a through 330e, the pressure sensor 245, the APC valve 244, the vacuum pump 246, the heater 207, the temperature sensor (not shown), the rotator 267, the elevator 115 and a transfer device 124 shown in FIG. 10.

The CPU 121a is configured to read the control program from the memory 121c and execute the control program. In addition, the CPU 121a is configured to read the process recipe from the memory 121c in accordance with an instruction such as an operation command inputted from the input/output device 122.

According to the contents of the process recipe read from the memory 121c, the CPU 121a may be configured to control various operations such as flow rate adjusting operations for various gases by the MFCs 320a through 320e, opening/closing operations of the valves 330a through 330e and an opening/closing operation of the APC valve 244. The CPU 121a may be further configured to control various operations such as a pressure adjusting operation by the APC valve 244 based on the pressure sensor 245, a start and stop of the vacuum pump 246, a temperature adjusting operation of the heater 207 based on the temperature sensor (not shown). The CPU 121a may be further configured to control various operations such as an operation of adjusting rotation and rotation speed of the boat 214 by the rotator 267, an elevating and lowering operation of the boat 214 by the elevator 115 and an operation of the transfer device 124 transferring the wafer 200 to or from the boat 214.

The controller 280 is not limited to a dedicated computer. The controller 280 may be embodied by a general-purpose computer. For example, the controller 280 according to the present embodiments may be embodied by preparing an external memory 123 storing therein the program and installing the program onto the general-purpose computer using the external memory 123. For example, the external memory 123 may include a magnetic disk such as a hard disk drive (HDD), an optical disk such as a CD, a magneto-optical disk such as an MO or a semiconductor memory such as a USB memory.

<Operation>

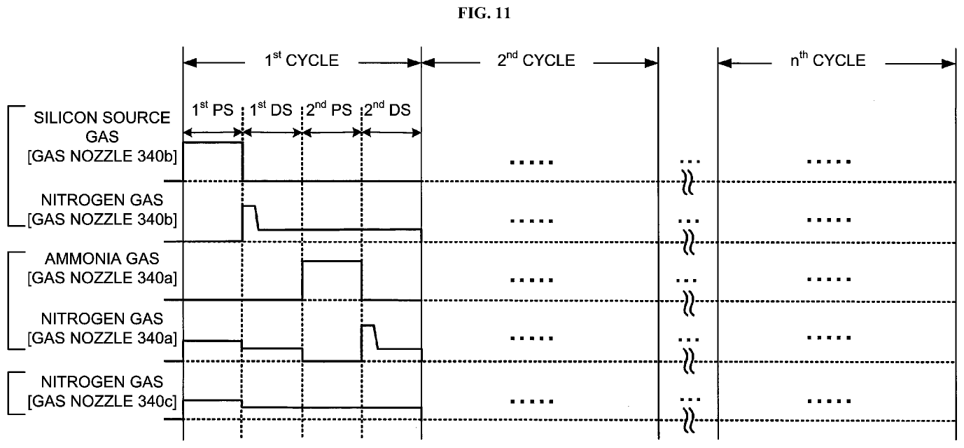

Hereinafter, an outline of the operations of the substrate processing apparatus 10 according to the present embodiments will be described according to a control procedure performed by the controller 280 by using a film-forming operation of a silicon nitride film shown in FIG. 11 as an example. The film-forming operation is controlled by the controller 280. First, the boat 214 on which a predetermined number of the wafers (that is, the wafers 200) are placed in advance is inserted into the reaction tube 203, and the reaction tube 203 is airtightly closed by the lid 219.

Then, the controller 280 controls the vacuum pump 246 and the APC valve 244 shown in FIG. 1 to exhaust an inner atmosphere of the reaction tube 203 through the exhaust port 230. In addition, the controller 280 controls the rotator 267 to start the rotation of the boat 214. The rotator 267 continuously rotates the boat 214 until at least a processing of the wafers 200 (also referred to as a “wafer processing”) is completed.

In a film-forming sequence shown in FIG. 11, the film-forming operation on the wafers 200 is completed by repeatedly performing a cycle a predetermined number of times. For example, the cycle includes a first processing step (“1^{st} PS” in FIG. 11), a first discharge step (“1^{st} DS” in FIG. 11), a second processing step (“2^{nd} PS” in FIG. 11) and a second discharge step (“2^{nd} DS” in FIG. 11). When the film-forming operation is completed, the boat 214 is transferred (unloaded) from the reaction tube 203. In addition, the wafers 200 are transferred from the boat 214 to a pod of a transfer shelf (not shown) by the transfer device 124, and the pod is transferred from the transfer shelf to a pod stage (not shown) by a pod transfer device (not shown). Then, the pod is transferred to an outside of a housing of the substrate processing apparatus 10 by an external transfer apparatus (not shown).

According to the present embodiments, the transfer device 124 inserts the end effector into the boat 214 through a side region of the boat 214, directly picks up the wafer 200 placed on the support pins 221 of the boat 214, and transfers the wafer 200 onto the end effector. A thickness of the end effector is smaller than a distance (for example, 13.25 mm) between the lower surface of the wafer 200 placed on the support pins 221 and the upper surface of the separation ring 400 directly below the wafer 200. For example, the thickness of the end effector is within a range from 3 mm to 6 mm. That is, since the thickness of the end effector is smaller than the distance between the lower surface of the wafer 200 and the upper surface of the separation ring 400 directly below the wafer 200 and the width and the thickness of the separation ring 400 are constant except for the contact portions between the separation ring 400 and the support columns 215a through 215e, the transfer device 124 can transfer the wafer 200 without interfering with the separation ring 400 even when the wafer 200 is picked up by the end effector according to the present embodiments. That is, the separation ring 400 may be provided without a notch through which the end effector passes when inserting the end effector into the separation ring 400. Thereby, it is possible to improve a uniformity of the wafer processing on the surface of the wafer 200.

Hereinafter, the cycle of the film-forming sequence shown in FIG. 11 will be described in detail. A vertical axis of a graph shown in FIG. 11 represents a gas supply amount, and a horizontal axis of the graph shown in FIG. 11 represents a timing of a gas supply in the film-forming sequence according to the present embodiments. Further, the valves 330a, 330b, 330c, 330d and 330e are closed before performing the cycle of the film-forming sequence.

<First Processing Step>

When the inner atmosphere of the reaction tube 203 is exhausted through the exhaust port 230 by the controller 280's control of each component of the substrate processing apparatus 10, the valves 330b, 330c and 330d are opened by the control of the controller 280 to eject the silicon (Si) source gas serving as the second source gas through the ejection holes 234b of the gas nozzle 340b. Further, the inert gas (nitrogen gas) is ejected through the ejection holes 234a of the gas nozzle 340a and the ejection holes 234c of the gas nozzle 340c. That is, by the control of the controller 280, the process gas is ejected through the ejection holes 234b of the gas nozzle 340b disposed in the second nozzle chamber 222b.

The valves 330d and 330c are opened by the control of the controller 280 to eject the inert gas (nitrogen gas) serving as a film thickness control gas through the ejection holes 234a of the gas nozzle 340a and the ejection holes 234c of the gas nozzle 340c. The film thickness control gas may refer to a gas capable of controlling the uniformity on the surface of the wafer 200. The uniformity on the surface of the wafer 200 may refer to a degree indicating that the thickness of the film does not vary particularly between the center and an edge of the wafer 200.

That is, the controller 280 performs the control such that the silicon source gas is supplied through the gas nozzle 340b and the inert gas is supplied through the gas nozzles 340a and 340c provided on both sides of the gas nozzle 340b. The silicon source gas is supplied toward the central axis of the boat 214 through the gas nozzle 340b. The inert gas is supplied toward the first exhaust outlet 236 and second exhaust outlet 237 along the edges of wafers 200 through the gas nozzle 340a and the gas nozzle 340c. When supplying the process gas, the gas nozzle 340b functions as a process gas supply structure. Further, the gas nozzles 340a and 340c function as an inert gas supply structure.

In the first processing step, the controller 280 controls the operations of the vacuum pump 246 and the APC valve 244 to discharge (or exhaust) the inner atmosphere of the reaction tube 203 through the exhaust port 230 while maintaining a pressure obtained (measured) from the pressure sensor 245 to be constant such that an inner pressure of the reaction tube 203 is lower than an atmospheric pressure.

<First Discharge Step>

When the first processing step is completed after a predetermined time has elapsed, the valve 330b is closed by the control of the controller 280 to stop a supply of the second source gas (that is, the silicon source gas) through the gas nozzle 340b. Further, the valve 330e is opened by the control of the controller 280 to start a supply of the inert gas (nitrogen gas) through the gas nozzle 340b. With the valves 330c and 330d open, flow rates adjusted by the MFCs 320c and 320d is reduced by the control of the controller 280 to eject the inert gas (nitrogen gas) serving as a backflow prevention gas through the ejection holes 234a of the gas nozzle 340a and the ejection holes 234c of the gas nozzle 340c. The backflow prevention gas may refer to a gas intended to prevent a diffusion of the gas from the process chamber 201 into the nozzle chambers 222. Alternatively, the backflow prevention gas may be supplied directly to the nozzle chambers 222 without passing through the gas nozzles such as the gas nozzle 340a and the gas nozzle 340c.

Further, the controller 280 also controls the operations of the vacuum pump 246 and the APC valve 244 to exhaust the inner atmosphere of the reaction tube 203 through the exhaust port 230, for example, by increasing a degree of a negative pressure in the reaction tube 203. In addition, immediately after opening the valve 330e, the inert gas can be supplied at a relatively large flow rate (preferably the same flow rate as the silicon source gas in the first processing step).

<Second Processing Step>

When the first discharge step is completed after a predetermined time has elapsed, the valve 330a is opened by the control of the controller 280 to eject the ammonia (NH₃) gas serving as the first source gas through the ejection holes 234a of the gas nozzle 340a. While ejecting the ammonia (NH₃) gas, the valve 330d is closed by the control of the controller 280 to stop the supply of the inert gas (nitrogen gas) serving as the backflow prevention gas from the gas nozzle 340a.

In the second processing step, the controller 280 controls the operations of the vacuum pump 246 and the APC valve 244 to discharge (or exhaust) the inner atmosphere of the reaction tube 203 through the exhaust port 230 while maintaining the pressure obtained (measured) from the pressure sensor 245 to be constant such that the inner pressure of the reaction tube 203 becomes a negative pressure.

<Second Discharge Step>

When the second processing step is completed after a predetermined time has elapsed, the valve 330a is closed by the control of the controller 280 to stop the supply of the first source gas through the gas nozzle 340a. Further, the valve 330d is opened by control of the controller 280 to eject the inert gas (nitrogen gas) serving as the backflow prevention gas through the ejection holes 234a of the gas nozzle 340a.

Further, the controller 280 also controls the operations of the vacuum pump 246 and the APC valve 244 to exhaust the inner atmosphere of the reaction tube 203 through the exhaust port 230, for example, by increasing the degree of the negative pressure in the reaction tube 203. In addition, immediately after opening the valve 330d, the inert gas can be supplied at a relatively large flow rate (preferably the same flow rate as the ammonia gas in the second processing step).

As described above, by repeatedly performing the cycle including the first processing step, the first discharge step, the second processing step and the second discharge step a predetermined number of times, the processing of the wafer 200 is completed.

Hereinafter, the embodiments of the present disclosure will be described in comparison with a comparative example.

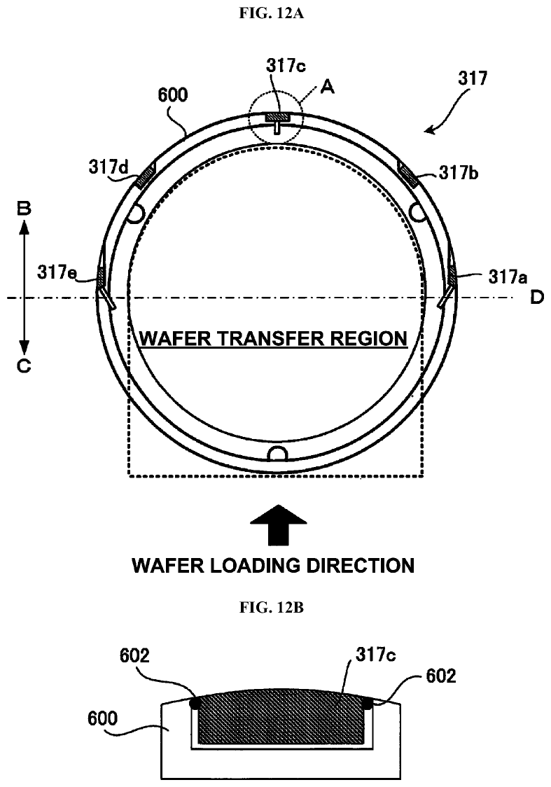

FIG. 12A is a diagram schematically illustrating a horizontal cross-section of a boat 317 according to a comparative example, and FIG. 12B is a diagram schematically illustrating an enlarged view of a periphery of welded portions 602 between a separation ring 600 and a support column 317c in a region “A” of FIG. 12A.

As shown in FIGS. 12A and 12B, in the boat 317 according to the comparative example, a plurality of support columns 317a through 317e are concentrated in a semicircular portion (that is, a region “B” shown in FIG. 12A) of the separation ring 600. In such a state, the support columns 317a through 317e and the separation ring 600 are directly welded and fixed. In other words, the separation ring 600 is fixed to the support columns 317a through 317e in the region “B” and is not fixed in a region “C”. As a result, the separation ring 600 is bent (droops or sags) toward the region “C” where the support columns 317a through 317e are not arranged, and a stress is concentrated at the welded portions 602 serving as fixing portions between the separation ring 600 and the support columns 317a through 317e. In such a case, a risk of contact between the boat 317 and the wafer 200 may increase when the wafer 200 is inserted into and placed on the boat 317, and a risk of damage to the boat 317 or the wafer 200 may also increase.

As shown in FIG. 13A, when a thickness of the separation ring 600 is increased in order to solve the problem described above, a bending (drooping or sagging) of the separation ring 600 may be reduced. However, the stress applied to the welded portions 602 between the separation ring 600 and the support columns 317a through 317e may be increased. Therefore, the thickness of the separation ring 600 can be increased within a range in which a sufficient strength can be maintained. In addition, when the thickness of the separation ring 600 is increased, an amount of heat for welding the separation ring 600 to the support columns 317a through 317e may be increased, and components (or structures) around the separation ring 600 may be distorted. That is, the thickness of the separation ring 600 is preferably set within a range from 0.5 mm to 6 mm, more preferably within a range from 1 mm or more and 4 mm or less.

Subsequently, a relationship between the thickness of the separation ring 400 or 600 and a gas inflow rate to the wafer 200 will be described in detail with reference to FIG. 13B. In FIG. 13B, the gas inflow rate to the wafer 200 is calculated by dividing a flow rate of the gas passing through a plane substantially perpendicular to a line connecting a center of the exhaust pipe 231 and the center of the wafer 200 with a flow rate of the gas supplied through the supply slits 235a, the supply slits 235b and the supply slits 235c. Further, as the wafer 200, a wafer whose diameter is 300 mm is used.

FIG. 13B is a diagram schematically illustrating the gas inflow rate to the wafer 200 when the thickness of the separation ring 600 is 3 mm (which is the comparative example) and when the thickness of the separation ring 400 is 1.5 mm (which is an example according to the present embodiments).

As shown in FIG. 13B, the gas inflow rate is about 86.8% when the boat 317 provided with the separation ring 600 whose thickness is 3 mm according to the comparative example is used, and the gas inflow rate is about 87.5% when the boat 214 provided with the separation ring 400 whose thickness is 1.5 mm according to the example of the present embodiments is used. That is, the gas inflow rate to the wafer 200 when the separation ring 400 whose thickness is 1.5 mm is used according to the present embodiments is higher than the gas inflow rate when the separation ring 600 whose thickness is 3 mm according to the comparative example is used. Therefore, it is confirmed that the gas inflow rate to the wafer 200 changes depending on the thickness of the separation ring 400 or 600.

Subsequently, a relationship between the inner diameter of the separation ring 400 or 600 and the gas inflow rate to the wafer 200 will be described in detail with reference to FIG. 13C. In FIG. 13C, the gas inflow rate to the wafer 200 is calculated in the same manner as described above. Further, as the wafer 200, a wafer whose diameter is 300 mm is used.

FIG. 13C is a diagram schematically illustrating the gas inflow rate to the wafer 200 when the inner diameter of the separation ring 600 is 286 mm (which is a first comparative example), when the inner diameter of the separation ring 600 is 291 mm (which is a second comparative example) and when the inner diameter of the separation ring 400 is 296 mm (which is an example according to the present embodiments).

As shown in FIG. 13C, the gas inflow rate is about 86.25% when the boat 317 provided with the separation ring 600 whose inner diameter is 286 mm according to the first comparative example is used, the gas inflow rate is about 87.3% when the boat 317 provided with the separation ring 600 whose inner diameter is 291 mm according to the second comparative example is used, and the gas inflow rate is about 87.5% when the boat 214 provided with the separation ring 400 whose inner diameter is 296 mm according to the example of the present embodiments is used. That is, the gas inflow rate to the wafer 200 when the separation ring 400 whose inner diameter is 296 mm is used according to the present embodiments is higher than the gas inflow rate when the separation ring 600 whose inner diameter is 286 mm according to the first comparative example or whose inner diameter is 291 mm according to the second comparative example is used. Therefore, it is confirmed that the gas inflow rate to the wafer 200 changes depending on the inner diameter of the separation ring 400 or 600.

That is, for example, the inner diameter of the separation ring 400 is preferably set to 296 mm. Further, it is confirmed that the thickness of the separation ring 400 is preferably set to be a thickness that does not obstruct the flow of the gas and does not pose the problem in terms of strength. For example, the thickness of the separation ring 400 is within a range from 1 mm to 2 mm. More specifically, for example, the thickness of the separation ring 400 is 1.5 mm.

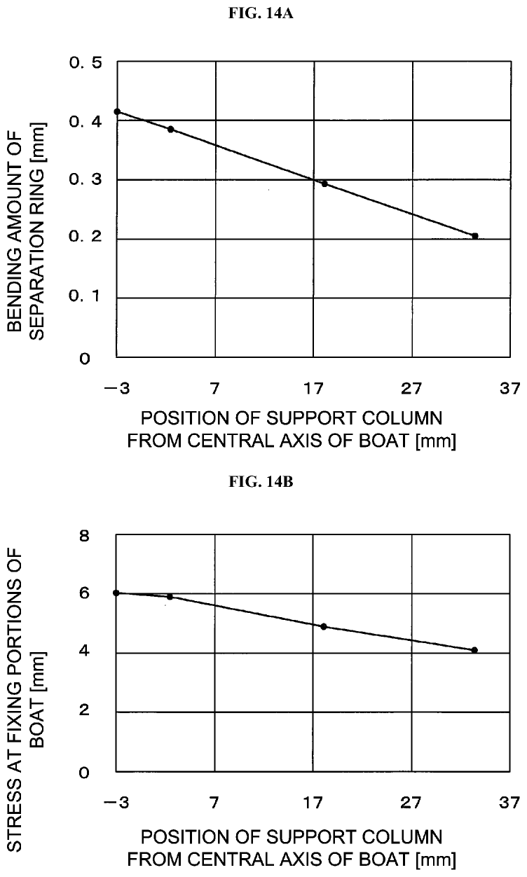

Subsequently, a relationship among positions of the support columns 317a and 317e provided at the front side with reference to the central axis of the boat 317 and the bending amount (the drooping amount or the sagging amount) of the separation ring 600 and a relationship among the positions of the support columns 317a and 317e provided at the frontside with reference to the central axis of the boat 317 and the stress generated in the fixing portions between the separation ring 600 and the support columns 317a through 317e will be described in detail with reference to FIGS. 12A, 12B, 14A and 14B.

As shown in FIGS. 14A and 14B, when the positions of the support columns 317a and 317e on the front side are changed to positions displaced forward by 32 mm from the central axis D of the boat 317 (that is, changed to positions spaced apart from the positions of the support columns 317a and 317e on the front side by 35 mm), respectively, the bending amount of the separation ring 600 and the stress in the fixing portions between the separation ring 600 and the support columns 317a through 317e are also reduced. That is, it is confirmed that both of the bending amount of the separation ring 600 and the stress in the fixing portions between the separation ring 600 and the support columns 317a through 317e can be reduced by arranging the support columns 317a and 317e configured to fix the separation ring 600 at positions displaced forward from the central axis D, more specifically, outside the wafer transfer region such that the support columns 317a and 317e do not interfere with the end effector when the end effector is inserted to transfer the wafer 200.

That is, both of the bending amount of the separation ring 600 and the stress in the fixing portions between the separation ring 600 and the support columns 317a through 317e can be reduced by moving the two support columns 317a and 317e on the front side to the positions in a front region (that is, the region “C” in FIG. 12A) similar to the support columns 215a and 215e of the boat 214 according to the present embodiments described above.

That is, according to the present embodiments, the support columns 215a and 215e of the boat 214 on the front side are moved to the positions outside the wafer transfer region toward the front side as much as possible. Then, instead of directly welding and connecting the separation ring 400 and the support columns 215a and 215e, the separation ring 400 and the support columns 215a and 215e are fixed by welding with the two rods 500a and 500b, respectively. Further, by providing the rod 500b of the curved shape, it is possible to mitigate (or reduce) the stress at the welded portions and a periphery thereof, and it is also possible to improve a strength of the boat 214.

Further, the pedestals 502 protruding from the support columns 215a and 215e toward the front side in the wafer loading direction are provided at the support columns 215a and 215e of the boat 214 on the front side, respectively. The pedestals 502 are configured such that the separation ring 400 is placed thereon. Thereby, it is possible to reduce the bending amount of the separation ring 400 and the stress in the fixing portions between the separation ring 400 and the support columns 215a and 215e, as compared with the comparative example.

### Other Embodiments

While the technique of the present disclosure is described in detail by way of the embodiments described above, the technique of the present disclosure is not limited thereto. The technique of the present disclosure may be modified in various ways without departing from the scope thereof.

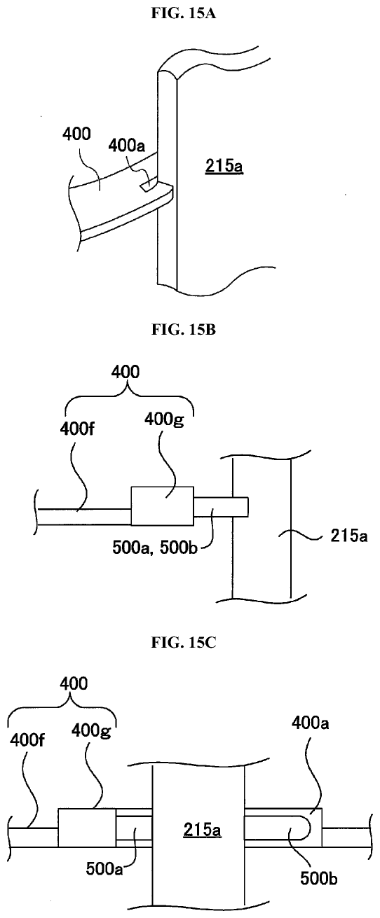

For example, instead of using the rods 500a and 500b, as shown in FIG. 15A, the separation ring 400 may be fixed by being placed on side surfaces (narrow surfaces) parallel to a width direction of the support columns 215a and 215e and being welded to the support columns 215a and 215e substantially perpendicular to the support columns 215a and 215e. By increasing a welding area as described above, it is possible to mitigate (or reduce) the stress concentrated on the fixing portions of the separation ring 400. In such a case, the notches 400a and 400e may be formed in a cutout shape in the circumferential direction such that the welded portions can be spaced apart from a main portion of the separation ring 400.

For example, as shown in FIGS. 15B and 15C, the diameter of each of the rods 500a and 500b connecting the separation ring 400 and the support columns 215a and 215e may be increased, and a thickness of portions (that is, a fixing portion 400g of the rods 500a and 500b for the separation ring 400 shown in FIGS. 15B and 15C) where the rods 500a and 500b of the separation ring 400 are respectively welded and connected may be set to be thicker than that of other portions (a ring portion 400f of the separation ring 400 shown in FIGS. 15B and 15C). Thereby, it is possible to ensure the weldability, and it is also possible to increase the welding area between the rods 500a and 500b and the separation ring 400. Further, it is also possible to mitigate (or reduce) the stress concentratedly applied on the fixing portions between the separation ring 400 and the support columns 215a through 215e.

While the technique of the present disclosure is described in detail by way of the embodiments and the modified examples described above, the technique of the present disclosure is not limited thereto. For example, the embodiments and the modified examples described above may be appropriately combined.

### SUMMARY

As described above, in the substrate processing apparatus 10 according to the technique of the present disclosure, it is possible to reduce the bending amount (the drooping amount or the sagging amount) of the separation ring 400. Further, it is possible to mitigate (or reduce) the stress at the welded portions and the periphery thereof, and it is also possible to improve the strength of the boat 214.

Further, the support columns 215a and 215e of the boat 214 on the front side and the separation ring 400 are fixed by being welded with the two rods 500a and 500b between the separation ring 400 and the rod 500a or the rod 500b, and the rod 500b is provided in the curved shape (or a bended shape). Thereby, it is possible to mitigate (or reduce) the stress at the welded portions and the periphery thereof, and it is also possible to improve the strength of the boat 214. That is, it is possible to absorb the deformation in the direction perpendicular to the extending direction of each of the rods 500a and 500b in the form of a bending moment by using the rods 500a and 500b. That is, by bending the rods 500a and 500b, it is possible to absorb the deformation in the up-and-down direction (vertical direction) of the substrate processing apparatus 10, the width direction (horizontal direction) of the substrate processing apparatus 10, and the depth direction (another horizontal direction) of the substrate processing apparatus 10. Thereby, it is possible to mitigate (or reduce) the stress at the welded portions and the periphery thereof, and it is also possible to improve the strength of the boat 214.

Further, by moving the support columns 215a and 215e of the boat 214 on the front side to the positions outside the wafer transfer region toward the front side as much as possible, it is possible to reduce the bending amount of the separation ring 400, and it is also possible to reduce the stress in the fixing portions between the separation ring 400 and the support columns 215a through 215e.

Further, by respectively providing the pedestals 502 protruding from the support columns 215a and 215e toward the front side at the support columns 215a and 215e, and supporting the separation ring 400 from thereunder, it is possible to reduce the bending amount of the separation ring 400, and it is also possible to reduce the stress in the fixing portions between the separation ring 400 and the support columns 215a through 215e.

Further, by using the boat 214 provided with the separation ring 400, it is possible to increase an inflow amount of the process gas onto the wafer 200, and it is also possible to improve the uniformity on the surface of the wafer 200. In addition, by suppressing a diffusion in an up-and-down direction of the wafer 200, it is possible to improve a uniformity of the wafer processing between the wafers 200.

Each of the support columns 215a through 215e is a polygonal column. Surfaces of the support columns 215a through 215e facing the inner periphery of the separation ring 400 are oriented substantially parallel to the wafer loading direction, and both circumferential side surfaces (i.e., side surfaces that face toward the circumferential direction of the separation ring 400) of each of the support columns 215a through 215e are substantially perpendicular to the circumferential direction. That is, the cross-section of each of the support columns 215a through 215e is of an asymmetrical shape that is longer in the circumferential direction of the separation ring 400 than in the width direction of the separation ring 400, and the outer peripheral surface of each of the support columns 215a through 215e is of a shape corresponding to the outer peripheral surface of the separation ring 400. The notches 400a through 400e are formed at the outer circumferential surface of the separation ring 400 so as to prevent the separation ring 400 from contacting the support columns 215a through 215e, respectively. The rods 500a and 500b are respectively welded to the surfaces of the separation ring 400 on which the notches 400a and 400e are provided and also to the side surfaces of the support columns 215a and 215e substantially perpendicular to a circumferential direction of each of the support columns 215a and 215e. That is, the rods 500a and 500b are provided in the gaps between the notches 400a and 400e and the support columns 215a and 215e, respectively. Thereby, the outer surface of the separation ring 400 and the outer surfaces of the support columns 215a through 215e of the boat 214 are configured to be continuous. Thereby, it is possible to substantially reduce (or minimize) the gap between the inner surface of the reaction tube 203 and the wafers 200 generated in the radial direction when the wafers 200 are stacked.

For example, the technique of the present disclosure is described in detail by way of the embodiments and the modified examples described above. However, the technique of the present disclosure is not limited thereto. It is apparent to the person skilled in the art that the technique of the present disclosure may be modified in various ways without departing from the scope thereof.

For example, the embodiments described above are described by way of an example in which the two support columns 215a and 215e on the front side of the boat 214 and the separation ring 400 are connected via the rods 500a and 500b, respectively. However, the technique of the present disclosure is not limited thereto. For example, the other support columns such as the support columns 215b, 215c and 215d and the separation ring 400 may be connected via the rods 500a and 500b, respectively. Alternatively, at least one of the support columns 215a through 215e and the separation ring 400 may be connected via the rods 500a and 500b.

For example, the embodiments described above are described by way of an example in which the separation ring 400 is provided between the adjacent wafers among the wafers stacked in the vertical direction. However, the technique of the present disclosure is not limited thereto. For example, the wafer 200 may be placed on the separation ring 400.

Although not specifically described in the embodiments described above, a halosilane-based gas, for example, a chlorosilane-based gas containing silicon and chlorine may be used as a source gas such as the second source gas. The chlorosilane-based gas also serves as a silicon source. For example, hexachlorodisilane (Si₂Cl₆, abbreviated as HCDS) gas may be used as the chlorosilane-based gas.

The source gas is not limited to a gas containing an element constituting the film. For example, the source gas may contain a catalyst or a reactant (also referred to as an “active species” or a “reducing agent”) which reacts with other source gases without providing the element constituting the film. For example, an atomic hydrogen may used as the first source gas to form a silicon film. For example, disilane (Si₂H₆) gas may be used as the first source gas and tungsten hexafluoride (WF₆) gas may be used as the second source gas to form a tungsten (W) film. In addition, the reactive gas may be any gas that reacts with other source gases no matter whether the element constituting the film is provided.

According to some embodiments of the present disclosure, it is possible to improve the strength of the substrate retainer.

What is claimed is:

1. A substrate retainer comprising:
a plurality of annular structures arranged at predetermined intervals;
a plurality of support columns configured to support the plurality of annular structures and provided along outer edges of the plurality of annular structures, wherein a width of each of the plurality of support columns is smaller than a width of each of the plurality of annular structures;
a plurality of support structures extending from the plurality of support columns toward a radially inward direction and configured to support a substrate between two adjacent annular structures among the plurality of annular structures; and
a plurality of connecting structures welded to at least one of the plurality of support columns and to the plurality of annular structures so as to connect the at least one of the plurality of support columns with the plurality of annular structures.

2. The substrate retainer of claim 1, wherein at least one of the plurality of connecting structures is of a curved shape so as to connect the at least one of the plurality of support columns with the plurality of annular structures.

3. The substrate retainer of claim 1, wherein two connecting structures among the plurality of connecting structures are provided between an annular structure among the plurality of annular structures and a support column among the plurality of support columns, and one of the two connecting structures is of a curved shape so as to connect the annular structure with the support column.

4. The substrate retainer of claim 1, wherein a notch is formed at each of the plurality of annular structures so as to prevent the plurality of annular structures from contacting the plurality of support columns, and
wherein each of the plurality of connecting structures is provided in a gap between a surface of each the plurality of annular structures where the notch is formed and a side surface of each of the plurality of support columns.

5. The substrate retainer of claim 1, wherein each of the plurality of connecting structures is of a round bar shape whose diameter is equal to or less than a thickness of each of the plurality of annular structures.

6. The substrate retainer of claim 1, wherein a cross-section of each of the plurality of support columns is of an asymmetrical shape that is longer in a circumferential direction of each of the plurality of annular structures than in a width direction of each of the plurality of annular structures.

7. The substrate retainer of claim 1, wherein an outer peripheral surface of each of the plurality of support columns is of a shape corresponding to an outer peripheral surface of each of the plurality of annular structures.

8. The substrate retainer of claim 1, wherein each of the plurality of annular structures is configured such that a thickness of portions of each of the plurality of annular structures where the plurality of connecting structures are respectively welded and connected is set to be thicker than a thickness of the other portions of each of the plurality of annular structures.

9. The substrate retainer of claim 1, wherein each of the plurality of support columns is a polygonal column, and
wherein both circumferential side surfaces of each of the plurality of support columns are substantially perpendicular to the circumferential direction, and
wherein the each of the plurality of connecting structures is respectively welded to both the circumferential side surfaces of each of the plurality of support columns.

10. The substrate retainer of claim 1, wherein each of the plurality of support columns is a polygonal column, and a surface of the each of the plurality of support columns facing an inner periphery of each of the plurality of annular structures is provided substantially parallel to a loading direction of the substrate.

11. The substrate retainer of claim 4, wherein the notch extends from a front end thereof to a rear end thereof wherein the front end and the rear end are defined along the loading direction of the substrate.

12. The substrate retainer of claim 1, wherein two support columns among the plurality of support columns located on a front side of each of the plurality of annular structures facing against a loading direction of the substrate are provided with a plurality of pedestals extending forward from the two support columns along a direction opposite to the loading direction of the substrate, respectively, and the plurality of pedestals are configured to support the plurality of annular structures from thereunder.

13. A substrate processing apparatus comprising:
a substrate retainer comprising:
a plurality of annular structures arranged at predetermined intervals;
a plurality of support columns configured to support the plurality of annular structures and provided along outer edges of the plurality of annular structures, wherein a width of each of the plurality of support columns is smaller than a width of each of the plurality of annular structures;
a plurality of support structures extending from the plurality of support columns toward a radially inward direction and configured to support a substrate between two adjacent annular structures among the plurality of annular structures; and
a plurality of connecting structures welded to at least one of the plurality of support columns and to the plurality of annular structures so as to connect the at least one of the plurality of support columns with the plurality of annular structures;
a reaction tube provided with a side surface and a ceiling and configured to accommodate the substrate retainer in a space surrounded by the side surface and the ceiling, wherein at least a part of the side surface is configured as a cylindrical surface;
a gas supply structure configured to supply a gas with respect to a surface of the substrate in the reaction tube; and
a gas exhaust structure configured to exhaust the gas supplied to the surface of the substrate.

14. The substrate processing apparatus of claim 13, wherein the gas supply structure is provided with a plurality of inlets open at substantially the same height as the substrate corresponding thereto, and the gas is supplied to the substrate through the plurality of inlets.

15. A method of manufacturing a semiconductor device, comprising:
(a) accommodating a substrate in a substrate retainer, wherein the substrate retainer comprises:
a plurality of annular structures arranged at predetermined intervals;
a plurality of support columns configured to support the plurality of annular structures and provided along outer edges of the plurality of annular structures, wherein a width of each of the plurality of support columns is smaller than a width of each of the plurality of annular structures;
a plurality of support structures extending from the plurality of support columns toward radially inward direction and configured to support the substrate between two adjacent annular structures among the plurality of annular structures in a vertical direction; and
a plurality of connecting structures welded to at least one of the plurality of support columns and to the plurality of annular structures so as to connect the at least one of the plurality of support columns with the plurality of annular structures;
(b) supplying a gas with respect to a surface of the substrate; and
(c) exhausting the gas supplied to the surface of the substrate.
